(19) United States
(12) Patent Application Publication
(10) Pub. No.: US 2012/0018716 A1
(43) Pub. Date: Jan. 26, 2012

(54) EMISSIVE SEMI-INTERPENETRATING POLYMER NETWORKS

(76) Inventors: Lihua Zhao, Sunnyvale, CA (US); Zhang-Lin Zhou, Palo Alto, CA (US); James A. Brug, Menlo Park, CA (US); Sity Lam, Pleasanton, CA (US); Gary Gibson, Palo Alto, CA (US)

(21) Appl. No.: 13/260,259

(22) PCT Filed: Jul. 31, 2009
(86) PCT No.: PCT/US09/52363

§ 371 Date: Sep. 24, 2011

(51) Int. Cl. H01L 51/54; C09K 11/02; C09K 11/08; C09K 11/06

(52) U.S. Cl. 257/40; 252/301.33; 252/301.35; 252/301.36; 257/E51.027

(57) ABSTRACT

An emissive semi-interpenetrating polymer network (E-semi-IPN) includes a semi-interpenetrating polymer network and an emissive material interlaced in the polymer network. The semi-interpenetrating polymer network includes in a crosslinked state one or more of a polymerized organic monomer and a polymerized organic oligomer, polymerized water soluble polymerizable agent, and one or more polymerized polyfunctional cross-linking agents. The E-semi-IPN may be employed as an E-semi-IPN layer (16, 36, 56) in organic light emitting devices (10, 20, 30, 40).

### CROSS-REFERENCE TO RELATED APPLICATIONS

N/A

### STATEMENT REGARDING FEDERALLY SPONSORED RESEARCH OR DEVELOPMENT

N/A.

### BACKGROUND

1. Technical Field

This invention relates to emissive semi-interpenetrating networks (semi-IPNs) and their preparation and use in light emitting devices.

2. Description of Related Art

Organic small molecule light emitting diodes (OLEDs) and polymer light-emitting diodes (PLEDs) have recently made significant progress toward applications in full color flat panel displays and other devices. Advances in the molecular design and synthetic methodology have made tremendous contributions.

Most advanced OLEDs comprise multilayer structures. Generally, two classes of multilayered devices are distinguished depending upon the materials involved: devices based on vacuum sublimation of small molecules and devices produced by means of wet-chemical deposition of conjugated oligomers and/or polymers. The sophisticated instruments for vacuum deposition of small molecules leads to relatively high production costs, which increase substantially as the area to be coated increases. By contrast, due to the simplicity of the solution processing and the reduced instrument cost, deposition from solution by various techniques appears more attractive than vacuum techniques.

One important issue related to solution processing is multilayer capability. Many light emitting devices comprise an emissive layer sandwiched between hole- and electron-transporting layers. For the fabrication of multilayer structures from solution, it is important that previously deposited layers be resistant to the solvent used to deposit an additional layer. Three different approaches are currently applied to such device fabrication. One common approach is to use “orthogonal” solvents for the individual layers, which means that the solvent used in a deposition does not dissolve the underlying layer(s). However, when depositing several layers from organic solvents, it is very difficult to achieve complete insolubility, which leads to intermixing of the components at the interface. Furthermore, the number of layers is limited because very few solvents can be used to dissolve typical OLED materials. Changing the polarity/solubility of the materials is another approach, but it has not yet proved successful. Another widely used approach is to introduce reactive moieties that can be polymerized to produce cross-linked systems after deposition. However, for this purpose, complicated synthetic work is required, such as introducing at least two or more reactive groups, for the purpose of cross-linking or further polymerization, onto either polymer backbones or precursors, which have to be compatible with the synthetic routes commonly used for the preparation of state-of-the-art OLED materials.

An interpenetrating polymer network is a polymer comprising two or more networks that are at least partially interlaced on a polymer scale but not covalently bonded to each other. The networks cannot be separated unless chemical bonds are broken. In general, in the formation of an interpenetrating polymer network, the two or more polymer networks are formed simultaneously. A semi-interpenetrating polymer network comprises one or more polymer networks and one or more linear or branched polymers characterized by the penetration on a molecular scale of at least one of the networks by at least some of the linear or branched chains. Semi-interpenetrating polymer networks differ from interpenetrating polymer networks because the constituent linear chain or branched chain polymers can be separated from the constituent polymer network without breaking chemical bonds. Semi-interpenetrating polymer networks may be prepared by sequential or simultaneous processes depending upon when the linear or branched polymer is incorporated into a preformed interpenetrating polymer or the polymer precursors .for the linear or branched polymer are incorporated into a mixture containing the precursors for the semi-interpenetrating polymer network and polymerized simultaneously.

### BRIEF DESCRIPTION OF THE DRAWINGS

The drawings provided herein are for the purpose of facilitating the understanding of certain embodiments of the present invention and are provided by way of illustration and not limitation on the scope of the appended claims.

FIG. 1 is a schematic diagram of an embodiment of alight-emitting device employing an emissive semi-interpenetrating polymer network (E-semi-IPN) in accordance with the present invention.

FIG. 2 is a schematic diagram of another embodiment of a light-emitting device employing an E-semi-IPN in accordance with the present invention.

FIG. 3 is a schematic diagram of another embodiment of a light-emitting device employing an E-semi-IPN copolymer in accordance with the present invention.

FIG. 4 is a schematic diagram of another embodiment of a light-emitting device employing an E-semi-IPN copolymer in accordance with the present invention.

FIG. 5 is a graph depicting UV-Vis spectra of illustrative sample E-semi-IPN (emissive material is a polyfluorene) thin films on ITO glass with and without toluene washing compared with polyfluorene-only films according to an embodiment of the present invention.

FIG. 6 is a graph depicting photoluminance (PL) spectra of illustrative sample E-semi-IPN (emissive material is a polyfluorene) thin films on ITO glass with and without toluene washing compared with polyfluorene-only films according to an embodiment of the present invention.

FIG. 7 is a graph depicting intensity-voltage (I-V) characteristics of illustrative sample E-semi-IPN OLEDs employing the emissive material of FIGS. 5-6 according to an embodiment of the present invention.

FIG. 8 is a graph depicting PL and Electroluminance (EL) spectra of illustrative sample E-semi-IPN OLEDs employing the emissive material of FIGS. 5-6 according to an embodiment of the present invention.

### DETAILED DESCRIPTION

### General Discussion

An embodiment of the present invention is an emissive semi-interpenetrating polymer network comprising a semi-interpenetrating polymer network and an emissive material interlaced in the polymer network. The semi-interpenetrating polymer network comprises in a crosslinked state (i) one or more of a polymerized organic monomer and a polymerized organic oligomer, (ii) polymerized water soluble polymerizable agent, and (iii) one or more polymerized polyfunctional cross-linking agents.

Another embodiment of the present invention is an organic light emitting device comprising a first electrode, a second electrode and an emissive semi-interpenetrating polymer network mentioned above disposed between the first electrode and the second electrode.

Another embodiment of the present invention is an emissive semi-interpenetrating polymer network comprising a semi-interpenetrating polymer network and a polyfluorene, polyfluorene derivative, a nanocrystal-polyfluorene hybrid, or a nanocrystal-polyfluorene derivative hybrid interlaced in the polymer network. The semi-interpenetrating network comprises in a crosslinked state (i) at least two of a polymerized diacrylate, a polymerized triacrylate and a polymerized tetraacrylate, and (ii) at least one of a polymerized acrylamide and a polymerized vinyl amide.

Another embodiment of the present invention is a composition for preparing an emissive semi-interpenetrating polymer network. The composition comprises a semi-interpenetrating polymer network-forming composition comprising one or more polyfunctional cross-linking agents, an organic polymer precursor wherein the polymer precursor is part of the polyfunctional cross-linking agent or is a separate entity, and a water soluble polymerizable agent. The composition for preparing the emissive semi-interpenetrating polymer network further comprises an emissive material. In some embodiments the composition further comprises a polymerization initiator. in some embodiments the composition further comprises an organic solvent.

Another embodiment of the present invention is a method of preparing an emissive semi-interpenetrating polymer network where the method comprises initiating the polymerization of the aforementioned composition.

Another embodiment of the present invention is a light-emitting device comprising a first electrode, a second electrode and an emissive semi-interpenetrating polymer network, prepared as discussed above, disposed between the first electrode and the second electrode.

Another embodiment of the present invention is an emissive semi-interpenetrating polymer network comprising, in a cross-linked state, one or more of a polymerized organic monomer and a polymerized organic oligomer, polymerized water insoluble polymerizable agent and one or more polymerized polyfunctional cross-linking agents. An emissive material is interlaced in the polymer network. The semi-interpenetrating polymer network may comprise one or more networked copolymers.

In some embodiments the emissive semi-interpenetrating polymer networks (E-semi-IPNs) described herein can be used for solution processed organic light emitting diodes (OLEDs). The present E-semi-IPNs are solvent resistant and as such, are resistant to damage from subsequent solution processing, which is one of the major problems in multi-layer solution-processed OLEDs. This enables fabrication of either bottom-emitting or top-emitting multi-layer devices that are not achievable by standard solution-based techniques for linear polymers. E-semi-IPN layers can be fabricated with good robustness and high voltage tolerance, thereby improving the performance of light-emitting devices and increasing the lifetime of such devices. In addition, the selected polymer network in semi-IPNs can affect the carrier mobility and help balance charges in OLED devices, as well as help to “lock” nanoscale species such as inorganic nanocrystals in their network structure, thus maintaining the desired distribution of the nanoscale species within the device structure.

Embodiments of the present E-semi-IPNs avoid the complexity of introducing reactive moieties to OLED materials. The methods described herein for the synthesis of E-semi-IPNs may be applied to any state-of-the-art OLED materials due to the broad choices for making the suitable polymer networks. Embodiments of the present methods for preparing E-semi-IPNs can significantly improve the chances of fabricating high quality/low cost OLEDs through solution processes such as, for example, spin-casting, dip-coating and printing technologies. Because the present E-semi-IPNs are highly solvent resistant, the subsequent layer of a light emitting device can be prepared without negative impact on the underlying one, and, in principle, the process can be repeated without limitation. Moreover, as mentioned above, embodiments of the present E-semi-IPNs are suitable for fabricating both bottom-emitting and top-emitting device structures, thereby making it more feasible to integrate OLED devices onto flexible roll-to-roll printed backplanes.

As discussed above, embodiments of the present E-semi-IPNs are easily incorporated into solution-processed organic light emitting diode devices as either an emitting layer or a host media as energy transfer sources. The present E-semi-IPNs protect the underlying organic layer because of the at least partial interlacing on a molecular level of emissive material in the semi-IPNs. The term “interlacing” or “interlaced” as used herein refers to the emissive material being incorporated in the semi-IPN, i.e., penetrated within the polymer network, but not covalently bonded to the networked copolymer(s) that form the semi-IPN.

In the process of preparing light emitting devices employing embodiments of the present E-semi-IPNs, a subsequent layer may be deposited from a solution comprising a solvent that could otherwise attack the unprotected underlying film. Besides high solvent resistance, the present E-semi-IPN layers can tolerate high electric fields and are robust, which is necessary for achieving high performance multi-layer OLED devices through simple solution processing. In addition, in some embodiments the selected polymer networks in the present E-semi-IPNs can affect the carrier mobility to help balance electrons and holes in OLED systems and also suppress the movement of nanoscale species such as inorganic nanocrystals, thus maintaining the desired distribution of these species within the organic device structure. More importantly, the present E-semi-IPNs contain an emissive and conducting component that is directly used as an emitter. The E-semi-IPNs also permit simplification of the resulting light-emitting device structure.

In some embodiments a composition for preparing an E-semi-IPN comprises (a) a polymer network-forming composition comprising (i) one or more polyfunctional cross-linking agents, (ii) a polymer precursor wherein the polymer precursor is part of the polyfunctional cross-linking agent or is a separate entity and (iii) a water soluble polymerizable agent, (b) an emissive material, (c) a polymerization initiator and (d) an organic solvent.

The polyfunctional cross-linking agents are organic molecules that comprise at least two carbon-carbon double bonds and two or more functionalities such as, for example, esters, amides, ethers, amidines, thioamides, sulfonamides, thioethers, carboxylates, sulfonates, phosphate esters, thioesters and oximes. The two or more functionalities may be the same for each molecule of polyfunctional cross-linking agent or they may be different. The functionalities are formed from reaction of at least two functional groups, which may be present on different moieties that form the molecule of polyfunctional cross-linking agent. Such functionalities include, for example, hydroxyl, amine, carboxyl, thiol, sulfonic acid, phosphoric acids and thiocarboxylic acids.

By way of illustration and not limitation, functional groups such as, for example, a non-oxocarbonyl group including nitrogen and sulfur analogs, a phosphate group, an amino group, an alkylating agent such as a halo group or a tosylalkyl group, an oxy (hydroxyl or the sulfur analog, mercapto) group, an oxocarbonyl (e.g., aldehyde or ketone) group, or an active olefin group such as a vinyl sulfone or an α-, β-unsaturated ester. The above functional groups may be linked to amine groups, carboxyl groups, alkylating agents, e.g., bromoacetyl. Functional groups that are a carboxylic acid or phosphate acid, on the one hand, and an alcohol on the other hand, react to form esters. An amine group and a carboxylic acid group, or its nitrogen derivative or phosphoric acid derivative, are functional groups that react to form amides, amidines and phosphoramides, respectively. Functional groups that are mercaptan (thiol) react to form thioethers such as, e.g., the reaction of a mercaptan and an alkylating agent. An aldehyde and an amine are functional groups that react under reducing conditions to form an alkylamine. A ketone group or an aldehyde group, on the one hand, reacts with a hydroxylamine (including derivatives thereof wherein a substituent is in place of the hydrogen of the hydroxyl group), on the other hand, to form an oxime functionality.

In some embodiments the polyfunctional cross-linking agents have a molecular weight greater than about 100, or greater than about 200, or greater than about 300, or greater than about 400, or greater than about 500, or greater than about 750, or greater than about 1000, or greater than about 1500 and less that about 10,000, or less than about 9000, or less than about 8000, or less than about 7000, or less than about 6000, or less than about 5000, or less than about 4000, or less than about 3000, for example. In some embodiments the polyfunctional cross-linking agent may comprise about 20 to about 200 atoms, or 20 to about 300 atoms, or about 20 to about 500 atoms, or about 40 to about 200 atoms, or about 50 to about 200 atoms, not counting hydrogen. The atoms of the polyfunctional cross-linking agent may be, for example, each independently selected from the group consisting of carbon, oxygen, sulfur, nitrogen, and phosphorous. In some embodiments the number of heteroatoms in the polyfunctional cross-linking agent is dependent on the size of the polyfunctional cross-linking and may range from about 2 to about 50 or more, or about 2 to about 40 or more, or about 2 to about 30 or more, or about 5 to about 50 or more, or about 5 to about 40 or more, or about 5 to about 30 or more, for example.

Examples of polyfunctional cross-linking agents, by way of illustration and not limitation, include multifunctional acrylates such as diacrylates, triacrylates, tetraacrylates, and the like. In some embodiments the multifunctional acrylates may include a portion or moiety that functions as a polymer precursor as described hereinbelow. Examples of multifunctional acrylate monomers or oligomers that may be employed as the polyfunctional cross-linking agent (some of which include a polymer precursor moiety) in the present embodiments, by way of illustration and not limitation, include diacrylates such as propoxylated neopentyl glycol diacrylate (available from Atofina Chemicals, Inc., Philadelphia Pa., as Sartomer SR 9003), 1,6-hexanediol diacrylate (Sartomer SR 238 from Sartomer Company, Inc., Exton Pa.), tripropylene glycol diacrylate, dipropylene glycol diacrylate, aliphatic diacrylate oligomer (CN 132 from Atofina), aliphatic urethane diacrylate (CN 981 from Atofina), and aromatic urethane diacrylate (CN 976 from Atofina), triacrylates or higher functionality monomers or oligomers such as amine modified polyether acrylates (available as PO 83 F, LR 8869, or LR 8889 from BASF Corporation), trimethylol propane triacrylate (Sartomer SR 351), tris (2-hydroxy ethyl) isocyanurate triacrylate (Sartomer SR 368), aromatic urethane triacrylate (CN 970 from Atofina), dipentaerythritol penta-/hexa-acrylate, pentaerythritol tetraacrylate (Sartomer SR 295), ethoxylated pentaerythritol tetraacrylate (Sartomer SR 494), and dipentaerythritol pentaacrylate (Sartomer SR 399), or mixtures of any of the foregoing. Additional examples of suitable cross-linking additives include chlorinated polyester acrylate (Sartomer CN 2100), amine modified epoxy acrylate (Sartomer CN 2100), aromatic urethane acrylate (Sartomer CN 2901), and polyurethane acrylate (Laromer LR 8949 from BASF).

Other examples of polyfunctional cross-linking agents include, for example, end-capped acrylate moieties present on such oligomers as epoxy-acrylates, polyester-acrylates, acrylate oligomers, polyether acrylates, polyether-urethane acrylates, polyester-urethane acrylates, and polyurethanes end-capped with acrylate moieties such as hydroxyethyl acrylate. Further, the polyurethane oligomer can be prepared utilizing an aliphatic diisocyanate such as hexamethylene diisocyanate, cyclohexane diisocyanate, diisocyclohexylmethane diisocyanate, isophorone diisocyanate, for example. Other examples include isophorone diisocyanate, polyester polyurethane prepared from adipic acid and neopentyl glycol, for example. Specific examples of polyfunctional cross-linking agents that include isocyanate functionalities and acrylate functionalities include materials sold by Sartomer Company such as, for example, CN966-H90, CN964, CN966, CN981, CN982, CN986, Pro1154 and CN301.

The amount of the polyfunctional cross-linking agent employed is dependent on a number of factors including the nature of the polyfunctional cross-linking agent, the nature and amount of the polymer precursor, the degree of cross-linking, the ability of good film-forming, the ability of charge permeating or blocking, for example. In some embodiments, the amount of polyfunctional cross-linking agent in a composition for preparing an E-semi-IPN may be about 10 to about 60%, or about 10 to about 40%, or about 10 to about 30%, or about 10 to about 20%, or about 20 to about 60%, or about 20 to about 50%, or about 20 to about 40%, or about 20 to about 30%, or about 30 to about 60%, or about 30 to about 50%, or about 30 to about 40%, for example (each being % by weight).

As indicated above, the polymer-network forming composition also comprises a polymer precursor, which may be a separate entity or may be part of the cross-linking agent or it may be another cross-linking agent that is different from the first cross-linking agent. The polymer precursor is an entity that is capable of being cross-linked with the cross-linking agent to form a semi-IPN. In some embodiments the polymer precursor may be, a monomer or an oligomer. Characteristics of monomers and oligomers that may be employed to form a semi-IPN include the presence of a polymerizable moiety (i.e., a reaction site available on the monomer or oligomer that may form chemical covalent bonds between monomers and/or oligomers; examples of such reaction sites include, e.g., carbon-carbon double bonds, carbon-carbon triple bonds and functional groups that react with one another such as those mentioned above with regard to the discussion of the cross-linking agents).

In some embodiments the monomers that are polymer precursors have a molecular weight of about 100 to about 500, or about 100 to about 400, or about 100 to about 300, or about 100 to about 200, or about 200 to about 500, or about 200 to about 400, or about 200 to about 300, for example. In some embodiments the monomers may comprise about 2 to about 200 atoms, or 2 to about 150 atoms, or about 2 to about 100 atoms, or about 2 to about 50 atoms, or about 5 to about 200 atoms, or 5 to about 150 atoms, or about 5 to about 100 atoms, or about 5 to about 50 atoms, or about 10 to about 200 atoms, or 10 to about 150 atoms, or about 10 to about 100 atoms, or about 10 to about 50 atoms, not counting hydrogen. The atoms of the monomer may be, for example, each independently selected from the group consisting of carbon, oxygen, sulfur, nitrogen, and phosphorous. In some embodiments the number of heteroatoms in the monomer is dependent on the size of the monomer and may range from about 1 to about 30, or about 1 to about 20, or about 1 to about 15, or about 1 to about 10, or about 1 to about 5, or about 2 to about 30, or about 2 to about 20, or about 2 to about 15, or about 2 to about 10, or about 2 to about 5, about 5 to about 30, or about 5 to about 20, or about 5 to about 15, or about 5 to about 10, for example.

The oligomer that may be a polymer precursor in accordance with present embodiments consists of a limited number of monomer units, the number of which determines the size of the oligomer. The monomer units of the oligomer may be the same or one or more or all of the monomer units may be different. In some embodiments the number of monomer units of the oligomer is about 2 to about 30, or about 2 to about 20, or about 2 to about 15, or about 2 to about 10, or about 2 to about 5, about 5 to about 30, or about 5 to about 20, or about 5 to about 15, or about 5 to about 10, for example. The monomer units are as discussed above with regard to the, monomeric polymer precursor.

Examples, by way of illustration and not limitation, of polymer precursors that may be employed in embodiments of the present invention include acrylates and derivatives thereof, styrenes and derivatives thereof, polyimide resins (an aromatic polyimide made by reacting pyromellitic dianhydride with an aromatic or aliphatic diamine), for example, AURUM® thermoplastic polyimide resin (E.I. du Pont de Nemours and Company, Del.); polyester emulsion aggregation resins (unsaturated resins formed by the reaction of dibasic organic acids and polyhydric alcohols), for example, 1-Alkyd resins, TAP Marine vinyl-ester resin (TAP Plastics, Mountain. View Calif.), and combinations of the aforementioned; polyfunctional cross-linking agents such as, e.g., diacrylates, triacrylates and tetraacrylates, and combinations of the aforementioned.

The amount of the polymer precursor employed is dependent on a number of factors including the nature and amount of the polyfunctional cross-linking agent and the polymer precursor, the degree of cross-linking, the ability of good film-forming, the ability of charge permeating or blocking, for example. In some embodiments, the amount of polymer precursor in a composition for preparing an E-semi-IPN may be about 10 to about 60%, or about 10 to about 40%, or about 10 to about 30%, or about 10 to about 20%, or about 20 to about 60%, or about 20 to about 50%, or about 20 to about 40%, or about 20 to about 30%, or about 30 to about 60%, or about 30 to about 50%, or about 30 to about 40%, for example (each being % by weight).

As mentioned above, in some embodiments a composition for preparing an E-semi-IPN comprises a water soluble polymerizable agent. The water soluble polymerizable agent is incorporated into the E-semi-IPN during the polymerization process by copolymerizing with the polyfunctional cross-linking agent and the polymer precursor. In some embodiments the water soluble polymerizable agent comprises a polymerizable moiety and a hydrophilic moiety. The function of the water soluble polymerizable agent is to provide for enhanced adherence of the E-semi-IPN forming composition to a substrate during polymerization to form a film comprising the E-semi-IPN on the surface of the substrate. The enhanced adherence contributes to the enhanced stability of the film during subsequent processing as discussed above. In some embodiments, the water soluble polymerizable agent is a hydrophilic monomer or hydrophilic oligomer that is water soluble.

The term “hydrophilic” (or “hydrophilicity”) refers to a moiety that is polar and thus prefers polar molecules and prefers polar solvents such as, e.g., water. Hydrophilic moieties have an affinity for other hydrophilic moieties compared to hydrophobic moieties. In some embodiments monomers or oligomers are hydrophilic because they comprise one or more hydrophilic functionalities or groups or moieties, which increases adherence of the semi-IPN forming composition to solid substrates, which are hydrophilic. Such functional group or functionality that forms part of the water soluble polymerizable agent can be a moiety having 1 to about 50 or more atoms (not counting hydrogen) where the atoms are selected from the group consisting of carbon and heteroatoms. The heteroatoms may be, for example, oxygen, sulfur, nitrogen, halogen and phosphorous. The number of heteroatoms in the hydrophilic moiety may range from 0 to about 20, or from 1 to about 15, or from 1 to about 6, or from 1 to about 5, or from 1 to about 4, or from 1 to about 3, or from 1 to 2, or from 0 to about 5, or from 0 to about 4, or from 0 to about 3, or from 0 to 2 or from 0 to 1.

The hydrophilic moiety can include a group comprising, for example, hydroxyl including polyhydroxyl, sulfonate, sulfate, phosphate, amidine, phosphonate, carboxylate, amine, ether, and amide. Illustrative functional groups include primary amines, secondary amines, tertiary amines, amides, nitrites, isonitriles, cyanates, isocyanates, thiocyanates, isothiocyanates, azides, thiols, thiolates, sulfides, sulfinates, sulfonates, phosphates, hydroxyls, polyhydroxyls or polyols (including glycols, etc.), alcoholates, phenolates, carbonyls, carboxylates, phosphines, phosphine oxides, phosphonic acids, phosphoramides, phosphates, carboxyalkyl, sulfonoxyalkyl, CONHOCH₂COOH, SO₂NHCH₂COOH, SO₃H, CONHCH₂CH₂SO₃H, PO₃H₂, OPO₃H₂, hydroxyl, carboxyl, ketone, and combinations thereof. Monomers or oligomers may already comprise one or more hydrophilic moieties or one or more may be introduced therein. Such a group or functionality may be introduced into a monomer or oligomer by methods that are well-known in the art for introducing such groups or functionalities into compounds. The number of functional groups from above that may be included in a hydrophilic monomer is that which is sufficient to render the hydrophilic monomer water soluble. The number of such functional groups in the hydrophilic moiety may be 1, or 2, or 3, or 4, or 5, or 6, or 7, or 8, or 9, or 10, for example.

As mentioned above, the water soluble polymerizable agent is water soluble. The phrase “water soluble” means that the solubility of the hydrophilic monomer in water at ambient temperature and pressure is at least 90%, or at least 91%, or at least 92%, or at least 93%, or at least 94%, or at least 95%, or at least 96%, or at least 97%, or at least 98%, or at least 99%, or at least 99.5%, or at least 99.6%, or at least 99.7%, or at least 99.8%, or at least 99.9%, or 100%, for example.

As mentioned above, the water soluble polymerizable agent also comprises a polymerizable moiety, i.e., a reaction site available on the monomer or oligomer that may form chemical covalent bonds between monomers and/or oligomers. Examples of such reaction sites include, e.g., carbon-carbon double bonds, carbon-carbon triple bonds and functional groups that react with one another such as those mentioned above with regard to the discussion of the cross-linking agents. The water soluble polymerizable agent may comprise one or more polymerizable moieties.

Examples, by way of illustration and not limitation, of hydrophilic monomers and oligomers that may be employed as water soluble polymerizable agents in the present embodiments include acrylamide and derivatives, for example, N-alkyl acrylamides, N-aryl acrylamides and N-alkoxyalkyl acrylamides. Specific examples include N-methyl acrylamide, N-ethyl acrylamide, N-butyl acrylamide, N,N-dimethyl acrylamide, N,N-dipropyl acrylamide, N-(1,1,2-trimethylpropyl) acrylamide, N-(1,1,3,3-tetramethylbutyl) acrylamide, N-methoxymethyl acrylamide, N-methoxyethyl acrylamide, N-methoxypropyl acrylamide, N-butoxymethyl acrylamide, N-isopropyl acrylamide, N-s-butyl acrylamide, N-t-butyl acrylamide, N-cyclohexyl acrylamide, N-(1,1-dimethyl-3-oxobutyl) acrylamide, N-(2-carboxyethyl) acrylamide, 3-acrylamide-3-methyl butanoic acid, methylene bisacrylamide, N-(3-aminopropyl) acrylamide to hydrochloride, N-(3,3 -dimethylaminopropyl) acrylamide hydrochloride, N-(1-phthalamidomethyl) acrylamide, sodium N-(1,1-dimethyl-2-sulfoethyl) acrylamide and the corresponding methacrylamides and combinations of two or more of the above mentioned compounds.

Further examples, by way of illustration and not limitation, of hydrophilic monomers and oligomers that may be employed as water soluble polymerizable agents in the present embodiments include N-vinyl amides, for example, N-methyl N-vinyl acetamide, N-vinyl acetamide, N-vinyl formamide and N-vinylmethacetamide; N-vinyl cyclic amides, for example, N-vinylpyrrolidone and N-vinyl-3-morpholinone; heterocyclic vinyl amines, for example, N-vinylpyridine, N-vinyloxazolidines, N-vinylpyrimidine, N-vinylpyridazine, N-vinyl-1,2,4-triazine, N-vinyl-1,3,5-triazine, N-vinyl-1,2,3-triazine, N-vinyl-triazole, N-vinyl-imidazole, N-vinylpyrrole and N-vinylpyrazine; polyethylene glycolated acrylates, for example, polyethylene glycoldi(meth)acrylate, ethylene glycol di(meth)acrylate, triethylene glycol di(meth)acrylate and tetraethylene glycol di(meth)acrylate; polyethylene glycolated methacrylates, for example, methylacrylamide glycolate methylether, polyethylene glycol mono(meth)acrylate, methoxypolyethylene glycol mono(meth)acrylate, octoxypolyethylene glycol mono(meth)acrylate and stearoxypolyethylene glycol mono(meth)acrylate; and combinations of two or more of the above mentioned compounds.

Further examples, by way of illustration and not limitation, of hydrophilic monomers and oligomers that may be employed as water soluble polymerizable agents in the present embodiments include cationic monomers, for example, N,N-dimethylaminoethyl methacrylate, N,N-dimethyl-aminoethyl acrylate, N,N-dimethylaminopropyl methacrylate, N,N-dimethylaminopropyl acrylate, N,N-dimethylacrylamide, N,N-dimethylmethacrylamide, N,N-dimethylaminoethylacrylamide, N,N-dimethylaminoethylmethacrylamide, N,N-dimethylaminopropylacrylamide, and N,N-dimethylaminopropyl-methacrylamide. In the case of tertiary amines, the compound would include an anion from a compound for forming a salt, for example, hydrochloric acid, sulfuric acid and acetic acid and combinations of two or more of the above mentioned compounds.

Further examples, by way of illustration and not limitation, of hydrophilic monomers and oligomers that may be employed as water soluble polymerizable agents in the present embodiments include anionic monomers, for example, unsaturated carboxylic acid monomers, e.g., acrylic acid, methacrylic acid, crotonic acid, itaconic acid, maleic acid, fumaric acid, citraconic acid and 2-methacryloyloxymethylsuccinic acid and their corresponding salts. Unsaturated sulfonic acid monomers include styrenesulfonic acid, 2-acrylamido-2-methylpropanesulfonic acid, 3-sulfopropyl(meth)acrylate and bis-(3-sulfopropyl)-itaconate as well as their corresponding salts. Unsaturated phosphoric acid monomers include vinylphosphonic acid, vinyl phosphate, bis(methacryloxyethyl)-phosphate, diphenyl-2-acryloyloxyethyl phosphate, diphenyl-2-methacryloyloxyethyl phosphate and dibutyl-2-acryloyloxyethyl phosphate. Combinations of two or more of the above mentioned compounds may also be employed.

The amount of the water soluble polymerizable agent employed is dependent on a number of factors including the nature and amount of the polyfunctional cross-linking agent and the polymer precursor, the nature of the substrate on which the composition is deposited for polymerization, and the ability of good-film formation, for example. In some embodiments, the amount of water soluble polymerizable agent in a composition for preparing an E-semi-IPN may be about 5 to about 30%, or about 5 to about 25%, or about 5 to about 20%, or about 5 to about 15%, or about 5 to about 10%, or about 10 to about 30%, or about 10 to about 25%, or about 10 to about 20%, or about 10 to about 15%, or about 5 to about 10%, for example (each being % by weight).

In some embodiments the composition for preparing an E-semi-IPN also comprises a polymerization initiator. The nature of the polymerization initiator is dependent on one or more of the nature of the polyfunctional cross-linking agent, the nature of the polymer precursor, and the type of polymerization, for example. In some embodiments the polymerization initiator is a thermal polymerization initiator, which includes, for example, organic peroxides, azo compounds and inorganic peroxides. Illustrative examples of organic peroxides include diacyl peroxide, peroxycarbonate and to peroxyester. In some embodiments the organic peroxide is a radical initiator such as isobutyl peroxide, lauroyl peroxide, stearyl peroxide, succinic acid peroxide, di-n-propyl peroxydicarbonate, diisopropyl peroxydicarbonate, bis(4-tert-butylcyclohexyl)peroxy-dicarbonate, for example. The inorganic initiators include ammonium persulfate, sodium persulfate, potassium persulfate, for example. Combinations of two or more of the above may also be employed.

In some embodiments the polymerization initiator is a photo-polymerization initiator, or UV polymerization initiator. Examples of photopolymerization initiators, by way of illustration and not limitation, include 2,4,6-trimethyl-benzoyldiphenylphosphine oxide (available as BASF Lucirin TPO), 2,4,6-trimethyl-benzoylethoxyphenylphosphine oxide (available as BASF Lucirin TPO-L), bis(2,4,6-trimethylbenzoyl)-phenyl-phosphine oxide (available as Ciba IRGACURE 819) and other acyl phosphines, 2-benzyl 2-dimethylamino 1-(4-morpholinophenyl) butanone-1 (available as Ciba IRGACURE 369), titanocenes, and isopropylthioxanthone, 1-hydroxy-cyclohexylphenylketone, benzophenone, 2,4,6-trimethylbenzophenone, 4-methyl-benzophenone, 2-methyl-1-(4-methylthio)phenyl-2-(4-morphorlinyl)-1-propanone, diphenyl-(2,4,6-trimethylbenzoyl) phosphine oxide, 2,4,6-trimethylbenzoylphenyl-phosphinic acid ethyl ester, oligo-(2-hydroxy-2-methyl-1-(4-(1-methylvinyl)phenyl) propanone), 2-hydroxy-2-methyl-1-phenyl-1-propanone, benzyl-dimethlylketal, t-butoxy-3,5,3-trimethylhexane, benzophenone, 2-hydroxy-2-methyl-1-phenyl-1-propanone, anisoin, benzil, camphorquinone, 1-hydroxycyclohexylphenyl ketone, 2-benzyl-2-dimethylamino-1-(4-morph-olinophenyl)-butan-1-one, 2,2-dimethoxy-2-phenylaceto-phenone, 2-methyl-1-[4-(methylthio)phenyl]-2-(4-morpholinyl)-1-propanone, for example, and mixtures or two or more of the above. Also included are amine synergists such as, for example, ethyl-4-dimethylaminobenzoate and 2-ethylhexyl-4-dimethylamino benzoate. This list is not exhaustive and any known photopolymerization initiator that initiates a free radical reaction upon exposure to a desired wavelength of radiation such as UV light can be used. Combinations of one or more of the above may also be employed in some embodiments.

The amount of the polymerization initiator employed is dependent on a number of factors including the nature and amount of the polyfunctional cross-linking agent and the polymer precursor, the nature of the polymerization and the polymerization initiator, and the degree of polymerization and cross-linking, for example. In some embodiments, the amount of polymerization initiator in a composition for preparing an E-semi-IPN may be about 0.5 to about 20%, or about 1 to about 20%, or about 1 to about 15%, or about 1 to about 10% or about 1 to about 5% or about 5 to about 20%, or about 5 to about 15%, or about 5 to about 10%, for example (each being % by weight).

The composition for forming the E-semi-IPN also comprises an emissive material, which is a substance that emits light with a wavelength ranging from about 380 nm to about 800 nm, for example. Any light emitting substance that can be incorporated into embodiments of the present E-semi-IPNs may be employed. The emissive material may be, for example, an organic polymer, a nanocrystal and a hybrid material containing organic polymers and inorganic nanocrystals, or combinations thereof. In some embodiments the emissive materials include conducting conjugated polymers with all different color emission (Red, Green, Blue (RGB) and white).

Light-emitting organic polymers that may be employed as the emissive material include, by way of illustration and not limitation, polymers comprising poly(p-phenylene vinylene), polyfluorene, poly(N-vinylcarbazole), poly(p-phenylene), poly(pyridine vinylene), polyquinoxaline, polyquinoline, polysilane, and derivatives of the aforementioned polymers such as alkyl derivatives, substituted alkyl derivatives, heteroalkyl (alkoxy, substituted alkoxy, thioalkyl, substituted thioalkyl) derivatives, alkenyl derivatives, substituted alkenyl derivatives, heteroalkenyl (alkenoxy, substituted alkenoxy, thioalkenyl, substituted thioalkenyl) derivatives, alkynyl derivatives, substituted alkynyl derivatives, heteroalkynyl (alkynoxy, substituted alkynoxy, thioalkynyl, substituted thioalkynyl) derivatives, aryl derivatives, substituted aryl derivatives, heteroaryl (aryloxy, substituted aryloxy, thioaryl, substituted thioaryl) derivatives, cyano derivatives, for example. By way of illustration and not limitation, alkyl derivatives of poly(fluorene), i.e., poly(alkylfluorenes), include, for example, poly(9,9-dihexylfluorene), poly(9,9-dioctylfluorene) (PFO) and poly(9,9-(2-ethylhexyl)-fluorene); alkyl derivatives of poly(p-phenylene) include, for example, poly(2-decyloxy-1,4-phenylene) and poly(2,5-diheptyl-1,4-phenylene). Mixtures of one or both of polymers and copolymers may also be used; various mixtures may be employed to obtain a particular color of emitted light, for example.

A specific example of an emissive organic polymer that may be employed in embodiments of the present composition, by way of illustration and not limitation, is a polymer comprising repeating monomer units having the formula:

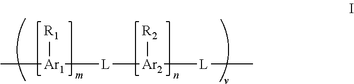

wherein:
Ar₁ and Ar₂ are independently an aromatic ring moiety,
L is independently a covalent bond directly linking Ar₁ and Ar₂ or a chemical moiety linking Ar₁ and Ar₂,
R₁ and R₂ are each independently selected from the group consisting of C₁-C₃₀ alkyl, C₂-C₃₀ alkenyl, C₂-C₃₀ alkynyl, C₁-C₃₀ aryl, C₁-C₃₀ alkoxy, C₂-C₃₀ alkenoxy, C₂-C₃₀ alkynoxy, C₁-C₃₀ aryloxy, C₁-C₃₀ thioalkyl, C₂-C₃₀ thioalkenyl, C₂-C₃₀ thioalkynyl, C₁-C₃₀ thioaryl, C(O)OR₄, N(R4)(R₅), C(O)N(R4)(R₅), F, Cl, Br, NO₂, CN, acyl, carboxylate and hydroxy, wherein R₄ and R₅ are each independently selected from the group consisting of hydrogen, C₁-C₃₀ alkyl and C₁-C₃₀ aryl,
m and n are integers independently between 1 and about 5,000, or between 10 and 4000, or between 10 and 3000, or between 10 and 2000, or between 10 and 1000, or between 10 and 500, or between 100 and about 5,000, or between 100 and 4000, or between 100 and 3000, or between 100 and 2000, or between 100 and 1000, or between 100 and 500, for example, and
v is an integer greater than about 10, or greater than about 50, or greater than about 100, for example.

In some embodiments Ar₁ and Ar₂ are each independently selected from the group consisting of phenyl, fluorenyl, biphenyl, terphenyl, tetraphenyl, naphthyl, anthryl, pyrenyl, phenanthryl, thiophenyl, pyrrolyl, furanyl, imidazolyl, triazolyl, isoxazolyl, oxazolyl, oxadiazolyl, furazanyl, pyridyl, bipyridyl, pyridazinyl, pyrimidyl, pyrazinyl, triazinyl, tetrazinyl, benzofuranyl, benzothiophenyl, indolyl, isoindazolyl, benzimidazolyl, benzotriazolyl, benzoxazolyl, quinolyl, isoquinolyl, cinnolyl, quinazolyl, naphthyridyl, phthalazyl, phentriazyl, benzotetrazyl, carbazolyl, dibenzofuranyl, dibenzothiophenyl, acridyl, and phenazyl.

In some embodiments the emissive material is a polymer comprising repeating monomer units having the formula:

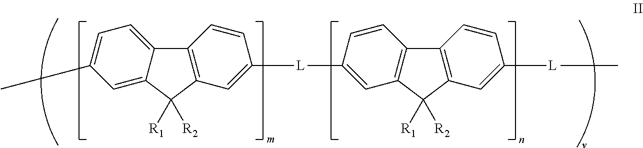

wherein:
L is independently a covalent bond directly linking the fluorenyl moieties or a chemical moiety linking the fluorenyl moieties,
R₁ and R₂ are each independently selected from the group consisting of C₁-C₃₀ alkyl, C₂-C₃₀ alkenyl, C₂-C₃₀ alkynyl, C₁-C₃₀ aryl, C₁-Cₘ alkoxy, C₂-C₃₀ alkenoxy, C₂-C₃₀ alkynoxy, C₁-C₃₀ aryloxy, C₁-C₃₀ thioalkyl, C₂-C₃₀ thioalkenyl, C₂-C₃₀ thioalkynyl, C₁-C₃₀ thioaryl, C(O)OR₄, N(R₄)(R5), C(O)N(R₄)(R₅), F, Cl, Br, NO₂, CN, acyl, carboxylate and hydroxy, wherein R₄ and R₅ are each independently selected from the group consisting of hydrogen, C₁-C₃₀ alkyl and C₁-C₃₀ aryl,
m and n are integers independently between 1 and about 5,000, and
v is an integer greater than about 10.

In some embodiments the emissive material may be an inorganic nanocrystal. In various embodiments, the nanocrystals are particles that may be of the same type or composition, or of two or more different types or compositions, and that have cross-sectional dimensions in a range from about 1 nanometer (nm) to about 500 nm, or from about 1 nm to about 400 nm, or from about 1 nm to about 300 nm, or from about 1 nm to about 200 nm, or from about 1 nm to about 100 nm, or from about 1 nm to about 50 nm, or from about 5 nm to about 500 nm, or from about 5 nm to about 400 nm, or from about 5 nm to about 300 nm, or from about 5 nm to about 200 nm, or from about 5 nm to about 100 nm, or from about 5 nm to about 50 nm, or from about 10 nm to about 500 nm, or from about 10 nm to about 400 nm, or from about 10 nm to about 300 nm, or from about 10 nm to about 200 nm, or from about 10 nm to about 100 nm, or from about 10 nm to about 50 nm.

In some embodiments, each nanocrystal comprises a substantially pure element. In some embodiments, each nanocrystal comprises a binary, tertiary or quaternary compound. In some embodiments E-semi-IPNs are synthesized in such a fashion to help prevent the nanocrystals from one or more of mobilizing, phase separating, segregating, and agglomerating to preserve a desired nanocrystal distribution.

In some embodiments the nanocrystal comprises an element selected from the group of elements (based on the periodic table of the elements) consisting of Group 2 (IIA) elements, Group 12 (IIB) elements, Group 13 (IIIA) elements, Group 3 (IIIB) elements, Group 14 (IVA) elements, Group 4 (IVB) elements, Group 15 (VA) elements, Group 5 (VB) elements, Group 16 (VIA) elements and Group 6 (VIB) elements and combinations of elements from one or more of the aforementioned groups.

In some embodiments, each nanocrystal may comprise a substantially pure element. In additional embodiments, each nanocrystal may include a binary, tertiary, or quaternary compound. Each nanocrystal may comprise one or more elements selected from Groups 2 (IIA), 12 (IIB), 3 (IIIB), 4 (IVB), 5 (VB) and 6 (VIB) of the periodic table, for example.

In some embodiments the nanocrystal comprises a metallic material such as, for example, gold, silver, platinum, copper, iridium, palladium, iron, nickel, cobalt, titanium, hafnium, zirconium, and zinc, in addition to or in lieu of one or more alloys thereof, oxides thereof, and sulfides thereof (such as, for example, Group 4 (IVB) oxides, TiO₂, ZrO₂, HfO₂, for example; or Groups 8-10 (VIII) oxides, Fe₂O₃, CoO, NiO, for example).

In some embodiments, each nanocrystal comprises a semiconductive material. By way of example and not limitation, each nanocrystal may comprise a III-V type semiconductor material (including, but not limited to InP, InAs, GaAs, GaN, GaP, Ga₂S₃, In₂S₃, In₂Se₃, In₂Te₃, InGaP, and InGaAs), or a Il-VI type semiconductor material (including, but not limited to, ZnO, CdSe, CdS, CdTe, ZnS, ZnSe, ZnTe, HgS, HgSe, and HgTe).

In some embodiments, each nanocrystal has a core-shell structure. For example, each nanocrystal may have an inner core region comprising a semiconductive material and an outer shell region comprising a passive inorganic material.

In some embodiments each nanocrystal has an inner core region comprising: (a) a first element selected from Groups 2 (IIA), 12 (IIIB), 13 (IIIA) 14 (IVA) and a second element selected from Group 16 (VIA); (b) a first element selected from Group 13 (IIIA) and a second element selected from Groups 15 (VA); or (c) an element selected from Group 14 (IVA). Examples of materials suitable for use in the semiconductive core include, but are not limited to, CdSe, CdTe, CdS, ZnSe, InP, InAs, or PbSe. Additional examples include MgS, MgSe, MgTe, CaS, CaSe, CaTe, SrS, SrSe, SrTe, BaS, BaSe, BaTe, ZnS, ZnTe, HgS, HgSe, HgTe, Al₂5₃, Al₂Se₃, Al₂Te₃, Ga₂S₃, Ga₂Se₃, GaTe, In₂S₃, In₂Se₃, InTe, SnS, SnSe, SnTe, PbS, PbSe, PbTe, AlP, AlAs, AlSb, GaN, GaP, GaAs, GaSb, InN, InSb, BP, Si, and Ge. Furthermore, the inner core region of each nanocrystal may comprise a binary, ternary or quaternary mixture, compound, or solid solution of any such elements or materials.

In some embodiments, each nanocrystal has an outer shell region comprising any of the materials previously described as being suitable for the inner core region of the nanocrystal. The outer shell region, however, may include a material that differs from the material of the inner core region. By way of example and not limitation, the outer shell region of each nanocrystal may include CdSe, CdS, ZnSe, ZnS, CdO, ZnO, SiO₂, Al₂O₃, or ZnTe. Additional examples include MgO, MgS, MgSe, MgTe, CaO, CaS, CaSe, CaTe, SrO, SrS, SrSe, SrTe,.BaO, BaS, BaSe, BaTe, CdTe, HgO, HgS, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, GeO₂, SnO, SnO₂, SnS, SnSe, SnTe, PbO, PbO₂, PbS, PbSe, PbTe, AlN, AlP, AlAs, AlSb, GaN, GaP, GaAs, GaSb, InN, and BP. Furthermore, the outer shell region of each nanocrystal may include a semiconductive material or an electrically insulating (i.e., non-conductive) material.

For incorporation into an E-semi-IPN in accordance with the present embodiments, the nanocrystal, in some embodiments, comprises a monomer, an oligomer or a polymer such as, for example, by binding thereto or complexing therewith to form a nanocrystal-monomer hybrid, a nanocrystal-oligomer hybrid or a nanocrystal-polymer hybrid. Suitable monomers and oligomers are as described above with regard to the polymer precursor. In some embodiments the monomer or oligomer is covalently bound to the nanocrystal by procedures that are known in the art. During the process for forming the E-semi-IPN, polymerization of the monomer-nanocrystal or oligomer-nanocrystal occurs and the resultant polymer becomes interlaced in the semi-IPN that is formed from the cross-linking agent and the polymer precursor. The conditions and reagents for forming the semi-IPN are chosen so that the polymerized nanocrystal becomes interlaced in, but not incorporated in such as by covalent bonding or copolymerization, the polymer network. On the other hand, in some embodiments, the monomer-nanocrystal or oligomer-nanocrystal may be polymerized in a separate step and the resultant polymer included as the emissive material in the composition for forming an E-semi-IPN. Polymerization conditions are well known to those skilled in the art.

In some embodiments, the nanocrystal may be bound to a polymer by virtue of binding groups in the polymer that bind to the nanocrystal. The polymer is a functionalized polymer, which contains binding groups that can covalently attach to the nanocrystals, thus forming a chemical complex or a covalent bond between each nanocrystal and a binding group. The binding group may be any functional group or structure that can either coordinate with or form a covalent bond with the nanocrystals so as to be chemically attached to the nanocrystals. The nature of the binding group is dependent on the nature and chemical composition of the nanocrystal, the size of the nanocrystal, any surface treatment of the nanocrystal, for example. The binding group may bind to a nanocrystal by a covalent bond or by a coordination bond (chemical complex).

By way of example and not limitation, the functional group may include at least one electron donating group (which may be electrically neutral or negatively charged). Electron donating groups often include atoms such as O, N, S, and P as well as combination thereof, for example, P=O groups, S=O groups and the like. By way of example and not limitation, the binding group may include a primary, secondary or tertiary amine or amide group, a nitrite group, an isonitrile group, a cyanate group, an isocyanate group, a thiocyanate group, an isothiocyanate group, an azide group, a thio group, a thiolate group, a sulfide group, a sulfinate group, a sulfonate group, a phosphate group, a hydroxyl group, an alcoholate group, a phenolate group, a carbonyl group, a carboxylate group, a phosphine group, a phosphine oxide group, a phosphonic acid group, a phosphoramide group, a phosphate group, a phosphite group, as well as combinations and mixtures of such groups.

One of the aforementioned functional groups may react with a corresponding functional group on a nanocrystal, by which the functional group is present on the particle or introduced on the surface of the nanocrystal. The products of the reactions of the functional groups are similar to those discussed above with regard to the polyfunctional cross-linking agents. In one embodiment, ligands can be provided and chemically attached to the nanocrystal. The ligands may include a binding group that is configured to form, a chemical bond or a chemical complex with a nanocrystal. The ligands may also include a functional group that is configured to react with binding group, which is a complementary functional group. The nanocrystals having the ligands bound thereto then may be mixed with the molecules of a polymer, and the complementary functional groups react with one another to form a covalently bonded link. Examples of ligands, by way of illustration and not limitation, include difunctional ligands such as amino acids, for example, alanine, cysteine, and glycine; aminoaliphatic acids, aminoaromatic acids, aminoaliphatic thiols, and aminoaromatic thiols, for example.

The amount of the emissive material employed is dependent on a number of factors including the nature of the emissive material (organic polymer, nanocrystal, for example), the nature of the device in which the E-semi-IPN is to be incorporated, the optical properties of the emissive material, for example. In some embodiments, the amount of emissive material in a composition for preparing an E-semi-IPN may be about 2 to about 50%, or about 5 to about 50%, or about 10 to about 50%, or about 20 to about 50%, or about 30 to about 50%, or about 40 to about 50%, or about 2 to about 40%, or about 5 to about 40%, or about 10 to about 40%, or about 20 to about 40%, or about 30 to about 40%, or about 2 to about 30%, or about 5 to about 30%, or about 10 to about 30%, or about 20 to about 30%, or about 2 to about 20%, or about 5 to about 20%, or about 10 to about 20%, for example (each being % by weight).

In some embodiments the composition for forming an E-semi-IPN is present in a solvent, which may be an organic solvent. A consideration for selection of the solvent is that it dissolves the composition for forming the E-semi-IPN. The nature of the organic solvent depends on one or more of the nature of the components of the composition, the nature of the substrate, the nature and condition of the cross-linking or polymerization process, and the nature of the initiators, for example. In some embodiments the solvent is a non-polar solvent such as, for example, an aromatic organic solvent including polyaromatic organic solvents, a hydrocarbon, a halogenated hydrocarbon, an ether, a formamide, and combinations of two or more of the above. Examples of organic solvents include, by way of illustration and not limitation, aromatic organic solvents such as benzene, toluene, xylene, chlorobenzene, dichlorobenzne, for example; hydrocarbons such hexane, heptane, dodecane, isopar L, isopar M, for example; halogenated hydrocarbons such as methylene chloride, chloroform, carbon tetrachloride, for example; ethers such as tetrahydrofuran, dioxane, for example; formamides such as dimethylformamide, for example; and combinations thereof.

The amount of the composition in the solvent is dependent on a number of factors including one or more of the nature of the components of the composition, the nature and conditions of the polymerization process, and the nature and condition of film-forming process, for example. In some embodiments, the amount of the composition for preparing an E-semi-IPN in the solvent may be about I to about 20%, or about 5 to about 20%, or about 10 to about 20%, or about 15 to about 20%, or about 1 to about 15%, or about 1 to about 10%, or about 1 to about 5%, or about 5 to about 15%, or about 5 to to about 10%, or about 10 to about 15%, or about 2 to about 20%, or about 2 to about 15%, or about 2 to about 10%, or about 2 to about 5%, for example (each being % by weight).

In one embodiment, by way of illustration and not limitation, the present invention can use both photo-curable and thermally curable resin compositions to generate the selected network in E-semi-IPNs. In this example, the composition comprises: (A) a polyimide resin having one or more primary alcoholic groups with an alcoholic equivalent equal to or less than about 3500, the polyimide resin being soluble in an organic solvent and having a weight average molecular weight of from about 5,000 to about 500,000; (B) at least one material selected from the group consisting of (i) a condensate of an amino compound modified with formalin, optionally further with alcohol, for example a melamine resin modified with formalin, optionally further with alcohol; (ii) a urea resin with formalin, optionally further with alcohol; and (iii) a phenol compound having, on average, at least two functionalities selected from the group consisting of a methylol group and an alkoxy methylol group, and (C) a photo acid generator capable of generating an acid upon irradiation with light of a wavelength of from 240 nm to 500 nm.

The conditions (e.g., temperature, duration, pH) for carrying out the process for forming the E-semi-IPN vary are dependent on a number of factors including, for example, the nature and amount of the components of the composition, the nature of the solvent, the nature of the polymerization including the nature of the polymerization initiator and the nature of the resulting devices that incorporate E-semi-IPN materials. In some embodiments the conditions for a thermal polymerization include reaction temperature, curing time, annealing process, post-annealing process, for example. In some embodiments the conditions for a photopolymerization include selection of photo-exposure sources, intensity, time and distance, temperature control and post annealing process, for example.

As mentioned above, in some embodiments the composition for forming an E-semi-IPN is disposed on a surface of a substrate prior to carrying out the polymerization process. The substrate may be fabricated from any suitable material for providing stability to a light emitting device and a suitable platform for one or more of the to layers of light-emitting device. Such materials include, for example, glass, metals, metal oxides, alloys, ceramics, semiconductor materials, plastics, and a combination of two or more of the above materials. Particular examples of such materials, by way of illustration and not limitation, include indium tin oxide (ITO), gold, silver, aluminum, polyethylene terephthalate (PET), polyethylene naphthalate (PEN), and SiO₂, and combinations of two or more of the above materials. The material for the substrate may be transparent, translucent or opaque depending on the manner in which the device is to be viewed, for example.

The thickness of the substrate is about 1 to about 500 nm, or about 1 to about 400 nm, or about 5 to about 500 nm, or about 5 to about 400 nm, or about 5 to about 300 nm, or about 5 to about 200 nm, or about 5 to about 100 nm, or about 10 to about 500 nm, or about 10 to about 400 nm, or about 10 to about 300 nm, or about 10 to about 200 nm, or about 10 to about 100 nm, or about 20 to about 500 nm, or about 20 to about 400 nm, or about 20 to about 300 nm, or about 20 to about 200 nm, or about 20 to about 100 nm, or about 30 to about 500 nm, or about 30 to about 400 nm, or about 30 to about 300 nm, or about 30 to about 200 nm, or about 30 to about 100 nm, or about 25 to about 250 nm, for example. The composition is disposed on the substrate and substrate having the composition disposed thereon, in some embodiments, will become an organic light emission layer in a light emitting device.

In some embodiments the solution of the composition is disposed on a surface of a substrate by solution processes such as, for example, spin-casting, solvent casting, dip-coating, screening technologies, printing technologies (including, e.g., inkjet deposition, screen printing and roll-to-roll printing), spin coating, slit coating, gravure coating, blade coating and spraying, for example, or a combination of two or more of the above. Following deposition, the composition is then treated under conditions for polymerization as discussed above.

As discussed above, using solution processing results in reduced instrument cost and enhanced multilayer capability. Because embodiments of the present E-semi-IPNs are highly solvent resistant, the subsequent layer in a light-emitting device can be prepared without negative impact on the underlying one Furthermore, because embodiments of the present E-semi-IPNs are highly solvent resistant, they are easily incorporated into solution-processed organic light emitting diode devices as either an emitting layer (EL) or host media as energy transfer sources. The present E-semi-IPNs protect the underlying organic layer, while the subsequent layer is deposited from a solution with a solvent that could attack the unprotected underlying film.

### Specific Embodiments of Light-Emitting Devices

The E-semi-IPNs of the present embodiments may be employed in a variety of applications. Such applications include, for example, light emitting diodes (LEDs) for information display applications, electromagnetic radiation sensors, lasers, photovoltaic cells, photo-transistors, modulators, phosphors, and photoconductive sensors. The devices of the aforementioned applications typically comprise a first electrode and a second electrode and have disposed between the first electrode and the second electrode an E-semi-IPN as described above. -In some embodiments the E-semi-IPN may be on the surface of a separate substrate or the E-semi-IPN may be on a surface of the one of the electrodes. The present E-semi-IPNs may be employed to provide local and uniform UV energy for emissive display applications. Embodiments of the present E-semi-IPNs find use as nanoscale UV energy sources in light-emitting devices and may be employed as, for example, emissive materials or layers in light-emitting diodes such as OLEDs, PLEDs and hybrid LEDs, which may be used in display devices.

The structure of a basic organic light emitting diode, comprises at least three layers, namely, two electrode layers and a light emission layer positioned between the two electrode layers. The two electrodes are connected to a power supply. In some embodiments the aforementioned E-semi-IPN may be stimulated by applying a voltage between the anode and the cathode, thereby generating an electric field extending across the E-semi-IPN. The electrical field between the anode and the cathode generates excitons (e.g., electron-hole pairs) in the E-semi-IPN. The E-semi-IPN may be selectively configured such that the allowed electron-hole energy states of the E-semi-IPN facilitate transfer of excitons. A photon of electromagnetic radiation having energy (i.e., a wavelength or frequency) corresponding to the energy of the exciton is emitted.

In some embodiments additional layers are included. For example, in some embodiments, the electrode (cathode) that is in connection with a negative pole of the power supply functions as an electron injection layer (EIL), which injects electrons into the light emission layer when a voltage is applied. The electrode (anode) in connection with the positive pole of the power supply functions as a hole injection layer (HIL), which injects holes into the light emission layer when a voltage is applied. When the electrons and the holes meet in the organic light emitting layer (EML), they recombine across the energy gap (energy difference between the lowest unoccupied molecular orbital (LUMO) and the highest occupied molecular orbital (HOMO) levels of the EML polymer). The energy released from the recombination of electrons and holes is in the form of light and the color is determined by the value of the energy gap. In some embodiments, the device is a multi-layer device, which has an extra polymeric layer that serves as an HIL using, for example, one or both of a polythiophene chemical, e.g., poly(3,4-ethylene-dioxythiophene (PEDOT), and DuPont™ Buffer™ (DB) from DuPont Displays, USA, DuPont OLEDs, Santa Barbara, Calif.

In addition to the basic structure as described above, an electron transport layer (ETL) may be added between the EIL and the EML, and a hole transport layer (HTL) may be added between the HIL and the EML. In embodiments in which they are employed, the ETL and HTL provide better energy band alignment between the EIL, the HIL and the EML, respectively, which would improve transporting of electrons and holes from the EIL and the HIL, respectively, into the EML. Furthermore, in some embodiments, an electron blocking layer (EBL) may be added between the HIL and the EML.

In some embodiments, a hole blocking layer (HBL) may be added between the EEL and the EML. The function of the EBL and the HBL is to block escaped electrons and holes, respectively, that fail to recombine with each other. If both an EBL and an HBL are present, the escaped electrons and holes can be confined in the EML without leaking through and being collected by the respective electrodes that would contribute wasteful power consumption and reduced light emission efficiency. When the escaped electrons and holes are confined in the EML by the presence of an EBL and an HBL, there is further opportunity for the electrons and holes to recombine and generate light and thus, emission efficiency is enhanced. Similarly, the EBL and the HBL may be inserted between the HTL, the ETL and the EML, respectively, if an HTL and an ETL are used. Alternatively, through proper choice of materials and/or synthesis, the HTL and the ETL could also serve as an EBL and an HBL, respectively.

As used herein, the phrases “positioned between” and “disposed between” mean that the organic light emission layer lies directly between two electrode layers or lies indirectly between two electrode layers where one or more intervening layers as discussed above lie between the organic light emission layer and one or both of the electrode layers.

The electrode layers may be obtained by techniques known in the art. Such techniques include, by way of illustration and not limitation, thermal or e-beam evaporation, sputtering or ion beam deposition with reactive gases (e.g., oxygen), nonreactive gases (e.g., argon, nitrogen), and mixtures of two or more of such gases. In the case of conducting electrodes using carbon nanotubes, metal nanoparticles or metal nanotubes, the electrode layers may be obtained by solution based techniques as discussed above. All other layers such as, for example, electron injection layer, electron blocking layer, electron transport layer, hole injection layer, hole blocking layer, hole transport layer and light emitting layer, which depend on their specific chemical compositions, may be processed either by vacuum processes or solution based processes as aforementioned. In addition, the present devices may be fabricated by sequentially laminating a first electrode, a film of the E-semi-IPN and a second electrode onto a substrate. Other layers may be included in the lamination process as appropriate.

The thickness of the light emission layer is described above. The thickness of the electrodes is independently about 0.1 to about 1000 nm, or about 0.1 to about 500 nm, or about 0.1 to about 400 nm, or about 0.1 to about 300 nm, or about 0.1 to about 200 nm, or about 0.1 to about 100 nm, or about 0.1 to about 50 nm, or about 1 to about 1000 nm, or about 1 to about 500 nm, or about 1 to about 400 nm, or about 1 to about 300 nm, or about 1 to about 200 nm, or about 1 to about 100 nm, or about 1 to about 50 nm, or to about 5 to about 750 nm, or about 5 to about 500 nm, or about 5 to about 400 nm, or about 5 to about 300 nm, or about 5 to about 200 nm, or about 5 to about 100 nm, or about 5 to about 50 nm, or about 10 to about 500 nm, or about 10 to about 400 nm, or about 10 to about 300 nm, or about 10 to about 200 nm, or about 10 to about 100 nm, or about 10 to about 50 nm, or about 50 to about 500 nm, or about 50 to about 400 nm, or about 50 to about 300 nm, or about 50 to about 200 nm, or about 50 to about 100 nm, for example.

As discussed above, the light-emitting devices may additionally include one or more of a hole injecting layer, an electron injecting layer; a hole transporting layer, an electron transporting layer, an electron blocking layer, and a hole blocking layer, .for example, as are known in the art. The devices may also include a protective layer or a sealing layer for the purpose of reducing exposure of the device to atmospheric elements. Furthermore, the devices may be one or both of covered with and packaged in an appropriate material.

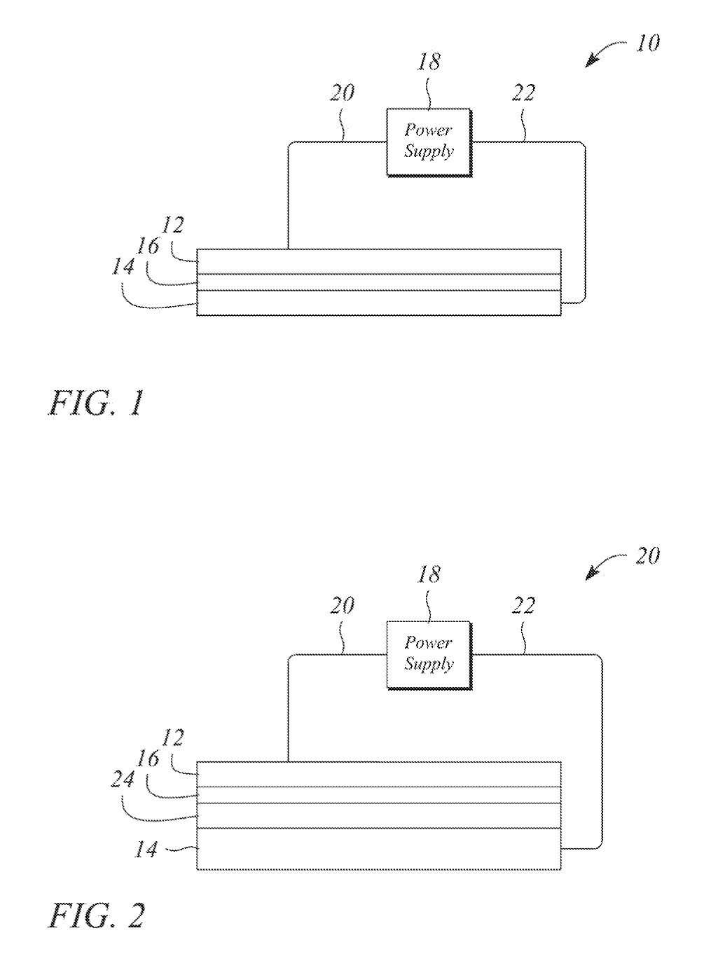

An example, by way of illustration and not limitation, of a device employing a fluorene-based copolymer in accordance with the present embodiments is depicted in FIG. 1. Referring to FIG. 1, light-emitting device 10 comprises first electrode 12 and second electrode 14. Disposed between electrodes 12 and 14 is layer 16 composed of an E-semi-IPN on a suitable substrate in accordance with the embodiments disclosed herein. Each of electrodes 12 and 14 is respectively connected to power supply 18 by means of lines 20 and 22. Power supply 18 is designed to separately activate electrode 12 and electrode 14.

Another example, by way of illustration and not limitation, of a device employing an E-semi-IPN in accordance with the present embodiments is depicted in FIG. 2. Referring to FIG. 2, light-emitting device 20 comprises first electrode 12 and second electrode 14 and hole-injecting layer 24. Disposed between electrode 12 and layer 24 is layer 16 composed of an E-semi-IPN on a substrate in accordance with the embodiments disclosed herein. Each of electrodes 12 and 14 is respectively connected to power supply 18 by means of lines 20 and 22. Power supply 18 is designed to separately activate electrode 12 and electrode 14.

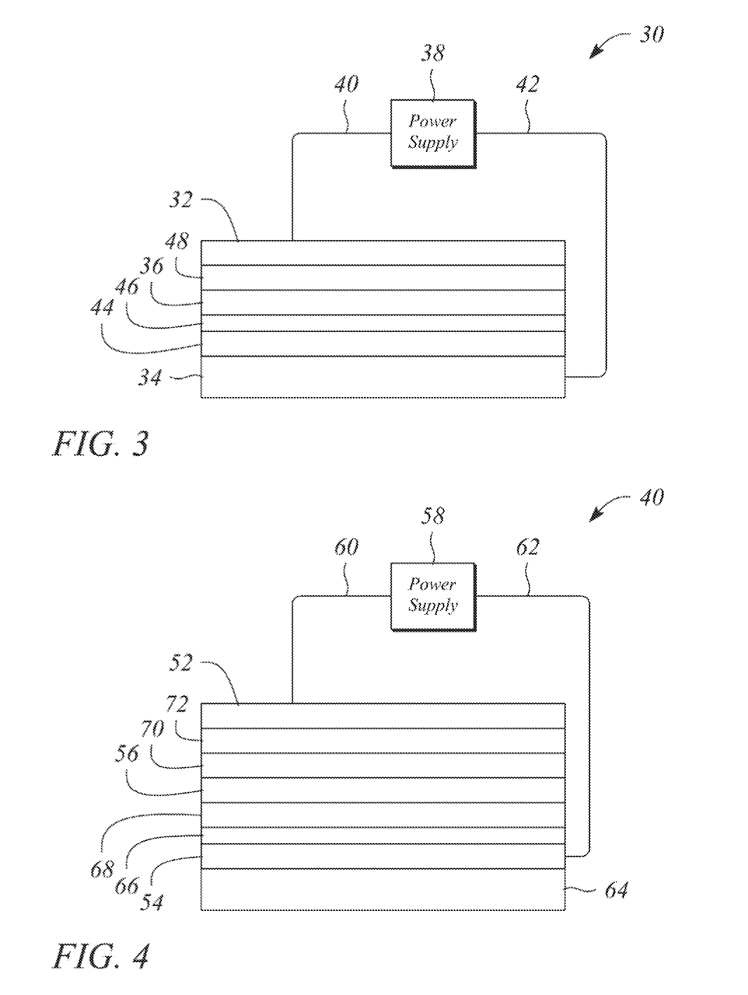

Another example, by way of illustration and not limitation, of a device employing an E-semi-IPN in accordance with the present embodiments is depicted in FIG. 3. Referring to FIG. 3, light-emitting device 30 comprises first electrode 32 and second electrode 34, hole injecting layer 44, hole transporting layer 46 and electron transporting layer 48. Disposed between layer 46 and layer 48 is layer 36 composed of an E-semi-IPN on a substrate in accordance with the embodiments disclosed herein. Each of electrodes 32 and 34 is respectively connected to power supply 38 by means of lines 40 and 42. Power supply 38 is designed to separately activate electrode 32 and electrode 34.

Another example, by way of illustration and not limitation, of a device employing an E-semi-IPN in accordance with the present embodiments is depicted in FIG. 4. Referring to FIG. 4, light-emitting device 40 comprises first electrode 52 and second electrode 54, hole injecting layer 66, hole transporting layer 68, electron transporting layer 70 and electron injecting layer 72. Disposed between layer 68 and layer 70 is layer 56 composed of an E-semi-IPN on a substrate in accordance with the embodiments disclosed herein. Each of electrodes 52 and 54 is respectively connected to power supply 58 by means of lines 60 and 62. Power supply 58 is designed to separately activate electrode 52 and electrode 54. Electrode 54 is disposed on support 64.

The anode may be formed from any material that has a relatively high work function, including metals such as but not limited to, gold, platinum, silver, copper, nickel, palladium, cobalt, selenium, vanadium, tungsten, and chromium, and combinations, alloys, oxides, sulfides and halides thereof, and including metal oxides such as, but not limited to, tin oxide, zinc oxide, indium oxide, indium tin oxide, and indium zinc oxide. In some embodiments, the anode may be formed from a conductive polymer such as, but not limited to, polyaniline, polypyrrole, polythiophene, and polyphenylene sulfide. Each of the aforementioned materials may be used individually or in combination and the anode may be formed in a single layer construction or a multilayer construction.

The cathode may be formed from a material that has a relatively low work function (i.e., the highest occupied electron energy level is very close to the vacuum to level) including metals such as, but not limited to, lithium, sodium, potassium, calcium, magnesium, aluminum, indium, ruthenium, titanium, manganese, yttrium, silver, lead, tin, and chromium, and alloys and oxides thereof. The cathode may be formed from an alloy of the aforementioned metals such as, for example, lithium-indium, sodium-potassium, magnesium-silver, aluminum-lithium, aluminum-magnesium, and magnesium-indium, or a metal oxide such as, for example, indium tin oxide. Each of the aforementioned materials may be used individually or in combination. The cathode may be formed in a single layer construction or a multilayer construction.

The support may be fabricated from any suitable material for providing stability to the device and a suitable platform for the layers of the device. Such materials include, for example, glass, metals, alloys, ceramics, semiconductor materials, and plastics, and a combination of two or more of the above materials. The material for the support may be transparent, translucent or opaque depending on the manner in which the device is to be viewed, for example.

The hole injecting (or injection) layer may be formed from any material that has a hole injecting property. Examples of such materials, by way of illustration and not limitation, include polymer-based hole injecting materials (for example, poly-(3,4-ethylenedioxythiophene)/polystyrenesulfonate (PEDOT:PSS), polythiophene compounds, polythienothiophene compounds, copolymers containing a carbazole and aromatic amine unit (for example, poly bis[6-bromo-N-(2-ethylhexyl)-carbazole-3-yl])); aromatic amine-based compounds such as those used as hole-transport materials in small-molecule, vapor-deposited OLEDs; metal oxides (for example, molybdenum oxide and vanadium oxide); DuPont™ Buffer™ film.

Materials for forming an electron injecting layer are also known in the art. Such materials include, for example, organic compounds having electron injecting properties and inorganic compounds such as, for example, certain salts of alkali metals and alkaline earth metals such as, for example, fluorides, carbonates, and oxides thereof. Specific examples, by way of illustration and not limitation, include LiF, CsCO₃, and CaO.

The electron blocking layer may be formed from a material that has a LUMO level that is higher than that of the EML and thus, forms a barrier to discourage electrons reaching the anode. This material may be a polymer-based chemical with high or low molecular weight. This material may also be a chemical compound comprising silicon, which may be, but is not limited to, an inorganic insulator layer made of SiO₂ or SiN, for example, or an organic silicon-based polymer such as siloxane, for example.

The hole blocking layer may be formed from a material that has a HOMO level that is lower than that of the EML and thus, forms a barrier to discourage holes reaching the cathode. Such a material may be, for example, a polymer-based chemical with high or low molecular weight or small organic molecules.

The thickness of each of the aforementioned additional layers, when employed in a device, may be independently about 0.1 to about 500 nm, or about 1 to about 500 nm, or about 1 to about 300 nm, or about 1 to about 250 nm, or about S to about 200 nm, or about 10 to about 150 nm, for example.

As mentioned above, the present devices may also comprise a protective layer or a sealing layer for the purpose of reducing exposure of the device to atmospheric elements such as, e.g., moisture, oxygen and debris, for example. Examples of materials from which a protective layer may be fabricated include inorganic films such as, for example, diamond thin films, films comprising a metal oxide or a metal nitride; polymer films such as, for example, films comprising a fluorine resin, polyparaxylene, polyethylene, a silicone resin, or a polystyrene resin; and photocurable resins. In addition, the device itself may be covered with, for example, glass, a gas impermeable film, a metal or the like, and the device may be packaged with an appropriate sealing resin.

Additional applications of embodiments of the present E-semi-IPNs include energy donor material for an inorganic-organic hybrid LED device. An inorganic-organic hybrid LED offers longer emission life, better color purity and flexibility in precision color tuning than either OLED or PLED devices.

### Specific Embodiments of E-semi-IPNs Employed in Light-Emitting Devices

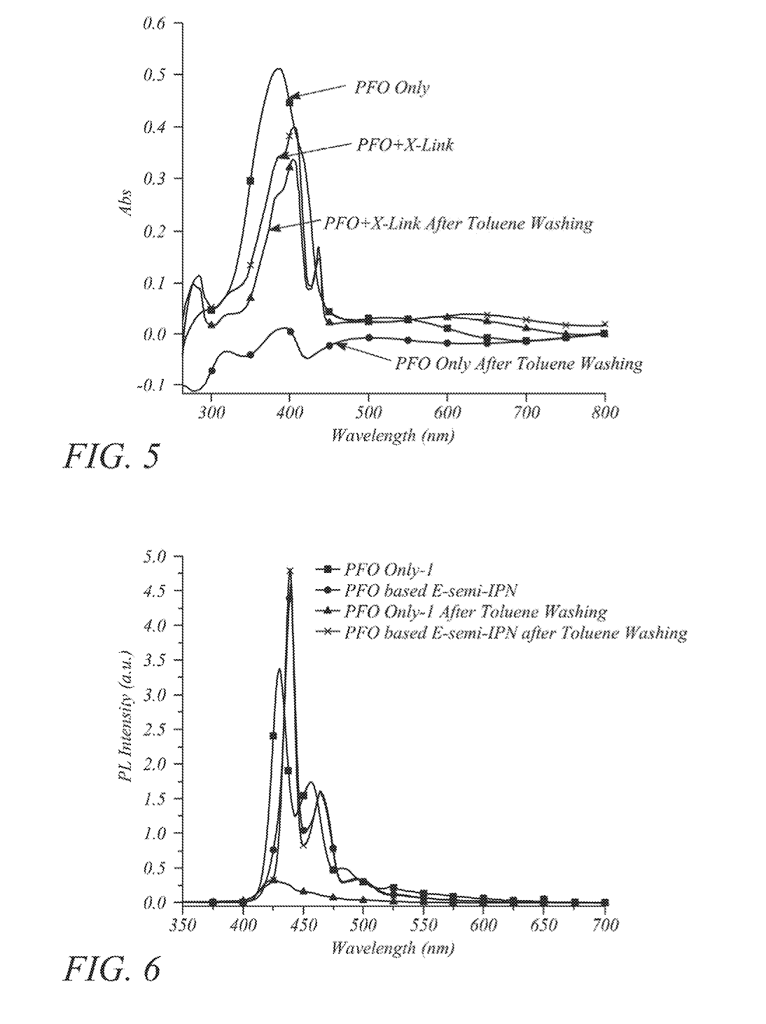

In an example, by way of illustration and not limitation, an organic polymer of the Formula II wherein R₁ and R₂ are both octyl (i.e., poly(9,9-dioctyl-2,7-fluorene) (PFO)) was studied. Four sample thin films were prepared on ITO substrates using the organic polymer PFO: (A) a PFO only thin film; (B) a PFO only thin film washed with toluene, (C) an E-semi-IPN thin film prepared from PFO and an X-solution (where the X-solution contains 20% of water soluble polymerizable agent N-vinylpyrrolidone, 40% ethoxylated bisphenol A dimethylacrylate, 35% trimethylolpropane trimethacrylate, 5% thermal initiator, tert-butoxy3,5,7-trimethylnexanoate, in toluene; thermally cured); (D) an E-semi-IPN thin film prepared from PFO and the X-solution further washed with toluene. UV-vis absorption and photoluminescence spectra were determined for samples (A)-(D) and the results are depicted in FIG. 5 and FIG. 6, respectively. FIG. 5 shows UV-vis spectra of sample E-semi-IPN thin films on ITO glass with and without toluene washing, compared with PFO only films, while FIG. 6 shows PL spectra of the same samples. For the PFO only films (A) and (B), the UV-vis absorbance of the films, after washing with toluene, decreases over 95% of its original value. However, for the E-semi-IPN film sample (D) after washing with toluene, the UV-vis absorbance remains more than 85% of its original value. In addition, photoluminance (PL) of the sample (D) shown in FIG. 6 remains the same compared with its original value where no washing with solvent occurred (represented by the E-semi-IPN film sample (C)). Moreover, the E-semi-IPN films showed, a higher PL intensity than PFO only films although the PFO absorbance (both peak and integral) of E-semi-IPN films is lower than PFO only films. This result suggests that E-semi-IPNs have a better PL efficiency, which is one of the important advantages for E-semi-IPNs used as an emissive layer in OLEDs over an emissive layer that is the PFO polymer only.

Another example, by way of illustration and not limitation, of a device employing an E-semi-IPN in accordance with the present embodiments is depicted in FIG. 3. Referring to FIG. 3, first electrode 32 is a low work function contact that may comprise a layer of aluminum as a cathode, and second electrode 34 is a high work function contact that may include a layer of transparent ITO as the anode. Hole injecting layer 44 may be a layer of poly(3,4-ethylenedioxythiophene) poly(styrenesulfonate) (PEDOT/PSS) or DuPont™ Buffer™ (DB).

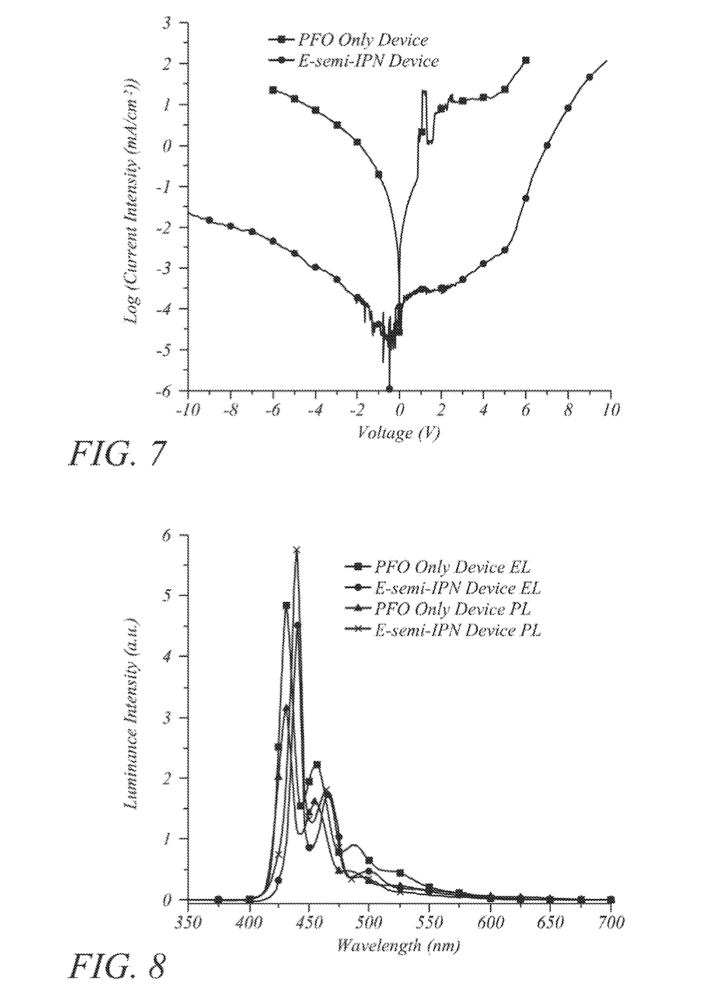

In another example, by way of illustration and not limitation, FIG. 7 shows the current-voltage characteristics of sample OLEDs made using the E-semi-IPNs (C) and (D) described above for FIG. 5 and FIG. 6 compared with a control device that included PFO polymer only (sample (A)). The sample E-semi-IPN OLEDs showed a significantly reduced current leakage compared to the PFO only device. FIG. 8 shows the PL spectra and Electroluminance (EL) spectra of the sample devices with E-semi-IPNs (samples (C) and (D) above) and without E-semi-IPNs (sample (A) above). As illustrated in FIG. 8, the PL spectra and the EL spectra of the sample devices are substantially matched. Examples of operated sample E-semi-IPN OLEDs, which were built with the E-semi-IPN layer washed with toluene at both 9V and 10V and whose spectra are compared in FIG. 8, exhibited bright blue emission.

### Discussion of Terms:

The following provides definitions for terms and phrases used above, which were not previously defined.

The phrase “at least” as used herein means that the number of specified items may be equal to or greater than the number recited. The phrase “about” as used herein means that the number recited may differ by plus or minus 10%; for example, “about 5” means a range of 4.5 to 5.5. The designations “first” and “second” are used solely for the purpose of differentiating between two items such as “first electrode” and “second electrode” and are not meant to imply any sequence or order or importance to one item over another.

The term “substituted” means that a hydrogen atom of a compound or moiety is replaced by another atom such as a carbon atom or a heteroatom. Substituents include, for example, alkyl, alkoxy, aryl, aryloxy, alkenyl, alkenoxy, alkynyl, alkynoxy, thio alkyl, thioalkenyl, thioalkynyl, thioaryl, and the like.

The term “heteroatom” as used herein means nitrogen, oxygen, phosphorus or sulfur. The terms “halo” and “halogen” mean a fluoro, chloro, bromo, or iodo substituent. The term “cyclic” means having an alicyclic or aromatic ring structure, which may or may not be substituted, and may or may not include one or more heteroatoms. Cyclic structures include monocyclic structures, bicyclic structures, and polycyclic structures. The term “alicyclic” is used to refer to an aliphatic cyclic moiety, as opposed to an aromatic cyclic moiety.

The phrase “aromatic ring system(s)” or “aromatic” as used herein includes monocyclic rings, bicyclic ring systems, and polycyclic ring systems, in which the monocyclic ring, or at least a portion of the bicyclic ring system or polycyclic ring system, is aromatic (exhibits, e.g., π-conjugation). The monocyclic rings, bicyclic ring systems, and polycyclic ring systems of the aromatic ring systems may include carbocyclic rings and/or heterocyclic rings. The term “carbocyclic ring” denotes a ring in which each ring atom is carbon. The term “heterocyclic ring” denotes a ring in which at least one ring atom is not carbon and comprises 1 to 4 heteroatoms.

The term “alkyl” as used herein means a branched, unbranched, or cyclic saturated hydrocarbon group, which typically, although not necessarily, contains from 1 to about 30 carbon atoms or more Alkyls include, but are not limited to, methyl, ethyl, n-propyl, isopropyl, n-butyl, isobutyl, t-butyl, octyl, decyl, and the like, as well as cycloalkyl groups such as cyclopentyl, cyclohexyl and the like. The term “lower alkyl” means an alkyl group having from 1 to 6 carbon atoms. The term “higher alkyl” means an alkyl group having more than 6 carbon atoms, for example, 7 to 30 carbon atoms or more. As used herein, the term “substituted alkyl” means an alkyl substituted with one or more substituent groups. The term “heteroalkyl” means an alkyl in which at least one carbon atom is replaced with a heteroatom. If not otherwise indicated, the term “alkyl” includes unsubstituted alkyl, substituted alkyl, lower alkyl, and heteroalkyl.

As used herein, the term “alkenyl” means a linear, branched or cyclic hydrocarbon group of 2 to about 30 carbon atoms or more containing at least one double bond, such as ethenyl, n-propenyl, isopropenyl, n-butenyl, isobutenyl, octenyl, decenyl, tetradecenyl, hexadecenyl, eicosenyl, tetracosenyl, and the like. The term “lower alkenyl” means an alkenyl having from 2 to 6 carbon atoms. The term “higher alkenyl” means an alkenyl group having more than 6 carbon atoms, for example, 7 to 30 carbon atoms or more. The term “substituted alkenyl” means an alkenyl or cycloalkenyl substituted with one or more substituent groups. The term “heteroalkenyl” means an alkenyl or cycloalkenyl in which at least one carbon atom is replaced with a heteroatom. If not otherwise indicated, the term “alkenyl” includes unsubstituted alkenyl, substituted alkenyl, lower alkenyl, and heteroalkenyl.

As used herein, the term “alkynyl” means a linear, branched or cyclic hydrocarbon group of 2 to about 30 carbon atoms or more containing at least one triple bond, such as ethynyl, n-propynyl, isopropynyl, n-butynyl, isobutynyl, octynyl, decynyl, tetradecynyl, hexadecynyl, eicosynyl, tetracosynyl, and the like. The term “lower alkynyl” means an alkynyl having from 2 to 6 carbon atoms. The term “higher alkynyl” means an alkynyl group having more than 6 carbon atoms, for example, 7 to 30 carbon atoms or more The term “substituted alkynyl” means an alkynyl or cycloalkynyl substituted with one or more substituent groups. The term “heteroalkynyl” means an alkynyl or cycloalkynyl in which at least one carbon atom is replaced with a heteroatom. If not otherwise indicated, the term “alkynyl” includes unsubstituted alkynyl, substituted alkynyl, lower alkynyl, and heteroalkynyl.

The term “alkylene” as used herein means a linear, branched or cyclic alkyl group in which two hydrogen atoms are substituted at locations in the alkyl group. Alkylene linkages thus include —CH₂CH₂— and —CH₂CH₂CH₂—, and so forth, as well as substituted versions thereof wherein one or more hydrogen atoms are replaced with a non-hydrogen substituent. The term “lower alkylene” refers to an alkylene group containing from 2 to 6 carbon atoms. The term “higher alkylene” means an alkylene group having more than 6 carbon atoms, for example, 7 to 30 carbon atoms or more. As used herein, the term “substituted alkylene” means an alkylene substituted with one or more substituent groups. As used herein, the term “heteroalkylene” means an alkylene wherein one or more of the methylene units are replaced with a heteroatom. If not otherwise indicated, the term “alkylene” includes heteroalkylene.

The term “alkenylene” as used herein means an alkylene containing at least one double bond, such as ethenylene (vinylene), n-propenylene, n-butenylene, n-hexenylene, and the like as well as substituted versions thereof wherein one or more hydrogen atoms are replaced with a non-hydrogen substituent. The term “lower alkenylene” refers to an alkenylene group containing from 2 to 6 carbon atoms. The term “higher alkenylene” means an alkenylene group having more than 6 carbon atoms, for example, 7 to 30 carbon atoms or more As used herein, the term “substituted alkenylene” means an alkenylene substituted with one or more substituent groups. As used herein, the term “heteroalkenylene” means an alkenylene wherein one or more of the alkenylene units are replaced with a heteroatom. If not otherwise indicated, the term “alkenylene” includes heteroalkenylene.

The term “alkynylene” as used herein means an alkylene containing at least one triple bond, such as ethynylene, n-propynylene, n-butynylene, n-hexynylene, and the like. The term “lower alkynylene” refers to an alkynylene group containing from 2 to 6 carbon atoms. The term “higher alkynylene” means an alkynylene group having more than 6 carbon atoms, for example, 7 to 30 carbon atoms. As used herein, the term “substituted alkynylene” means an alkynylene substituted with one or more substituent groups. As used herein, the term “heteroalkynylene” means an alkynylene wherein one or more of the alkynylene units are replaced with a heteroatom. If not otherwise indicated, the term “alkynylene” includes heteroalkynylene.

The term “alkoxy” as used herein means an alkyl group bound to another chemical structure through a single, terminal ether linkage. As used herein, the term “lower alkoxy” means an alkoxy group, wherein the alkyl group contains from 1 to 6 carbon atoms, and includes, for example, methoxy, ethoxy, n-propoxy, isopropoxy, t-butyloxy, etc. The term “higher alkoxy” means an alkoxy group wherein the alkyl group has more than 6 carbon atoms, for example, 7 to 30 carbon atoms or more. As used herein, the term “substituted alkoxy” means an alkoxy substituted with one or more substituent groups. The term “heteroalkoxy” means an alkoxy in which at least one carbon atom is replaced with a heteroatom. If not otherwise indicated, the term “alkoxy” includes unsubstituted alkoxy, substituted alkoxy, lower alkoxy, and heteroalkoxy.

The term “alkenoxy” as used herein means an alkenyl group bound to another chemical structure through a single, terminal ether linkage. As used herein, the term “lower alkenoxy” means an alkenoxy group, wherein the alkenyl group contains from 2 to 6 carbon atoms, and includes, for example, ethenoxy, n-propenoxy, isopropenoxy, t-butenoxy, etc. The term “higher alkenoxy” means an alkenoxy group wherein the alkenyl group has more than 6 carbon atoms, for example, 7 to 30 carbon atoms or more. As used herein, the term “substituted alkenoxy” means an alkenoxy substituted with one or more substituent groups. The term “heteroalkenoxy” means an alkenoxy in which at least one carbon atom is replaced with a heteroatom. If not otherwise indicated, the term “alkenoxy” includes unsubstituted alkenoxy, substituted alkenoxy, lower alkenoxy, higher alkenoxy and heteroalkenoxy.

The term “alkynoxy” as used herein means an alkynyl group bound to another chemical structure through a single, terminal ether linkage. As used herein, the term “lower alkynoxy” means an alkynoxy group, wherein the alkynyl group contains from 2 to 6 carbon atoms, and includes, for example, ethynoxy, n-propynoxy, isopropynoxy, t-butynoxy, etc. The term “higher alkynoxy” means an, alkynoxy group wherein the alkynyl group has more than 6 carbon atoms, for example, 7 to 30 carbon atoms or more. As used herein, the term “substituted alkynoxy” means an alkynoxy substituted with one or more substituent groups. The term “heteroalkynoxy” means an alkynoxy in which at least one carbon atom is replaced with a heteroatom. If not otherwise indicated, the term “alkynoxy” includes unsubstituted alkynoxy, substituted alkynoxy, lower alkynoxy, higher alkynoxy and heteroalkynoxy.

The term “thioalkyl” as used herein means an alkyl group bound to another chemical structure through a single, terminal thio (sulfur) linkage. As used herein, the term “lower thioalkyl” means a thioalkyl group, wherein the alkyl group contains from 1 to 6 carbon atoms, and includes, for example, thiomethyl, thioethyl, thiopropyl, etc. The term “higher thioalkyl” means a thioalkyl group wherein the alkyl group has more than 6 carbon atoms, for example, 7 to 30 carbon atoms or more. As used herein, the term “substituted thioalkyl” means a thioalkyl substituted with one or more substituent groups. The term “heterothioalkyl” means a thioalkyl in which at least one carbon atom is replaced with a heteroatom. if not otherwise indicated, the term “thioalkyl” includes unsubstituted thioalkyl, substituted thioalkyl, lower thioalkyl, and heterothioalkyl.

The term “thioalkenyl” as used herein means an alkenyl group bound to another chemical structure through a single, terminal thio (sulfur) linkage. As used herein, the term “lower thioalkenyl” means a thioalkenyl group, wherein the alkenyl group contains from 2 to 6 carbon atoms, and includes, for example, thioethenyl, thiopropenyl, etc. The term “higher thioalkenyl” means a thioalkenyl group wherein the alkenyl group has more than 6 carbon atoms, for example, 7 to 30 carbon atoms or more As used herein, the term “substituted thioalkenyl” means a thioalkenyl substituted with one or more substituent groups. The term “heterothioalkenyl” means a thioalkenyl in which at least one carbon atom is replaced with a heteroatom. If not otherwise indicated, the term “thioalkenyl” includes unsubstituted thioalkenyl, substituted thioalkenyl, lower thioalkenyl, and heterothioalkenyl.

The term “thioalkynyl” as used herein means an alkynyl group bound to another chemical structure through a single, terminal thio (sulfur) linkage. As used herein, the term “lower thioalkynyl” means a thioalkynyl group, wherein the alkyl group contains from 2 to 6 carbon atoms, and includes, for example, thioethynyl, thiopropylynyl, etc. The term “higher thioalkynyl” means a thioalkynyl group wherein the alkynyl group has more than 6 carbon atoms, for example, 7 to 30 carbon atoms. As used herein, the term “substituted thioalkynyl” means a thioalkynyl substituted with one or more substituent groups. The term “heterothioalkynyl” means a thioalkynyl in which at least one carbon atom is replaced with a heteroatom. If not otherwise indicated, the term “thioalkynyl” includes unsubstituted thioalkynyl, substituted thioalkynyl, lower thioalkynyl, and heterothioalkynyl.

The term “aryl” means a group containing a single aromatic ring or multiple aromatic rings that are fused together, directly linked, or indirectly linked (such that the different aromatic rings are bound to a common group such as a methylene or ethylene moiety). Aryl groups described herein may contain, but are not limited to, from 5 to 30 carbon atoms. Aryl groups include, for example, phenyl, naphthyl, anthryl, phenanthryl, biphenyl, diphenylether, diphenylamine, benzophenone, and the like. The term “substituted aryl” refers to an aryl group comprising one or more substituent groups. The term “heteroaryl” means an aryl group in which at least one carbon atom is replaced with a heteroatom. If not otherwise indicated, the term “aryl” includes unsubstituted aryl, substituted aryl, and heteroaryl.

The term “aryloxy” as used herein means an aryl group bound to another chemical structure through a single, terminal ether (oxygen) linkage. The term “phenoxy” as used herein is aryloxy wherein aryl is phenyl.

The term “thioaryl” as used herein means an aryl group bound to another chemical structure through a single, terminal thio (sulfur) linkage. The term “thiophenyl” as used herein is thioaryl wherein aryl is phenyl.

### EXAMPLES

Unless otherwise indicated, materials in the experiments below may be purchased from Aldrich Chemical Company, St. Louis Mo. Percentages are by weight unless indicated otherwise.

### Example 1

### Preparation of X-solution

To a vial were added N-vinylpyrrolidone (20%), ethoxylated bisphenol A dimethylacrylate (40%), trimethylolpropane trimethylacrylate (35%) and tert-butoxy-3,5,7-trimethylhexanoate (5%). Toluene, as solvent, was added to the above mixture to form a solution (referred to herein as X-solution) with a concentration of 10%.

### Example 2

### Preparation of an Embodiment of a Polymer-Only E-semi-IPN

To X-solution (1 mL), prepared as described above, was added a solution of PFO (6 mg) in toluene (1 mL). The resulting mixture was stirred for 1 hour at room temperature. The well-mixed solution was deposited by spin-casting on a quartz substrate (for characterization) and on an ITO-coated glass with DuPont™ Buffer™ (DB) film (DuPont OLEDs, Santa Barbara Calif.) (for OLEDs). The resulting films (PFO-based) were annealed at 135° C. for 1 hour and cooled to room, temperature for future use

### Example 3

### Preparation of Additional Embodiments of a Polymer-Only E-semi-IPN

To achieve different colors, the procedure described above in Example 2 was employed to prepare E-semi-IPNs from other conducting polymers, namely, poly[2-methoxy-5-(-ethylhexyloxy)-phenylene-vinylene] (MEH-PPV) and 9-dioctylfluorene-co-benzothiadiazole) (F8BT). The films of each of the above E-semi-IPNs were deposited either directly on a substrate (quartz or ITO glass) or on top of PFO-based E-semi-IPNs. The PFO-based E-semi-IPNs, the MEH-PPV-based E-semi-IPNs and the F8BT-based E-semi-IPNs represent polymer-based E-semi-IPNs.

### Example 4

### Sample Preparation for Characterization of Polymer-Based E-semi-IPN Films

One of two PFO-based E-semi-IPN films on ITO-coated glass (prepared by a procedure similar to that described in Example 2), was washed with toluene by spin-coating. The resulting film was referred to as “PFO-based E-semi-IPN after toluene washing,” referred to above as sample (D). Both films were annealed at 110° C. for 1 hour and cooled to room temperature. As references, two PFO-only films were prepared by spin-coating PFO solution with a concentration of 6 mg/mL in toluene and annealed at 135° C. for 1 hour and cooled to room temperature. One of these PFO-only films was then washed with toluene by spin coating. The resulting film was referred as “PFO-only-1 after toluene washing,” referred to above as sample (B). Both of these latter films were also annealed at 110° C. for 1 hour and cooled to room temperature. The final films, “PFO-only-1,” referred to above as sample (A), “PFO-based E-semi-IPN,” referred to above as sample (C), “PFO-only-1 after toluene washing,” referred to above as sample (B), and “PFO-based E-semi-IPN after toluene washing,” referred to above as sample (D), were characterized by UV-Vis spectra and photoluminance (PL) spectra shown, respectively, in FIG. 5 (UV-Vis) and FIG. 6 (PL).

### Example 5

### Fabrication and Testing of Embodiments of Polymer-Based OLED Devices

ITO-coated glass substrates were cleaned by O₂ plasma. DB solution, as a hole injection material, was deposited on the cleaned ITO-coated glass substrates by spin-coating. The resulting DB films were annealed at the appropriate temperature, for example, 100° C. After cooling room temperature, “PFO based E-semi-IPN” film and “PFO based E-semi-IPN after toluene washing” film, as emission layers, respectively prepared as described in Example 3, were deposited on the top of DB layers. “PFO-only” and “PFO-only after toluene washing” films, as references, were also respectively prepared as described in. Example 3. Al was then thermally deposited to finish the full stack of OLEDs shown in FIG. 4. These sample OLED devices were tested and characterized by I-V characteristics and electroluminance spectra shown in FIG. 7 and FIG. 8, respectively.

### Example 6

### Fabrication of Additional Embodiments of Polymer-Based OLED Devices

Other devices were prepared as described above and included a thermally deposited layer, which was deposited to the stack prior to deposition of Al. The layers differed from device to device as follows: layer of Ba (device A), layer of Ca (device B), layer of LiF (device C), and layer of Cs₂CO₃ (device D); representing layers of low work function. Devices A-D were prepared for PFO, MEH-PPV and F8BT, respectively, as the emissive material of the E-semi-IPNs.

### Example 7

### Preparation of an Embodiment of a Nanocrystal-Only E-semi-IPN

To X-solution (1 mL), prepared as described in Example 1 above, is added a chloroform solution of CdSe/ZnS nanocrystals (2 mg/1 mL, 1 mL). The resulting mixture is stirred for a few hours at room temperature. The well-mixed solution is deposited by spin-casting on a substrate; quartz or ITO-coated glass for characterization, or ITO-coated glass with DB film for OLEDs. The resulting films are annealed at 135° C. for 1 hour. In some embodiments a layer of electron-transporting material, polypyridine, may be deposited by spin-casting on top of the as-prepared nanocrystal-based E-semi-IPN For the ITO-coated glass sample, Al is then thermally deposited to finish the full stack of OLEDs. In some embodiments a low work function material is also thermally deposited before Al deposition (see Example 6). To achieve different colors, in some embodiments CdSe/ZnS nanocrystals with different sizes ranging from 2-8 nm, are employed.

### Example 8

### Preparation of an Embodiment of a Polymer-Nanocrystal E-semi-IPN

To the X-solution (1 mL), prepared as described in Example 1 above was added a chloroform solution (1 mL) of CdSe/ZnS nanocrystals (2mg/1 mL) and PFO (4 mg/mL). The resulting mixture was stirred for a few hours at room temperature. The well-mixed solution was deposited by spin-casting on a substrate, namely, quartz or ITO-coated glass for characterization, or ITO-coated glass with DB film for OLEDs. The resulting films were annealed at 135° C. for 1 hour. For ITO-coated glass sample, Al was then thermally deposited to finish the full stack of the OLED. For some devices, a layer of electron-transporting materials, namely, polypyridine, may be deposited by spin-casting on top of the Polymer-Nanocrystal E-semi-IPN film.

### Example 9

### Fabrication of Additional Embodiments of Polymer-Nanocrystal-Based OLED Devices

Other devices were prepared as described above and included a thermally deposited layer, which was deposited to the stack prior to deposition of Al. The layers differed from device to device as follows: layer of Ba (device A), layer of Ca (device B), layer of LiF (device C), and layer of Cs₂CO3 (device D); representing layers of low work function. Devices A-D were prepared for PFO-nanocrystal, MEH-PPV-nanocrystal and F8BT-nanocrystal, respectively, as the emissive material of the E-semi-IPNs.

### Example 10

### Preparation of an Embodiment of a Functionalized Polymer-Nanocrystal Complex E-semi-IPN

To the X-solution (1 mL), prepared as described in Example 1 above is added a chloroform solution (1 mL) of a complex of CdSe/ZnS nanocrystals and a functionalized organic polymer (2mg/1 mL). The polymer is of the Formula II wherein R₁ and R₂ arc both hexyl for one fluorene ring and R₁ and R₂ are both aminohexyl for the other fluorene ring wherein the amine groups are on the terminal carbon of the hexyl group. The functionalized polymer is prepared by polymerizing appropriate hexyl and terminally functionalized hexyl fluorene monomers, resulting in a product in which the fluorene groups are linked directly in the resulting polymer. The mixture is stirred for a few hours at room temperature. The well-mixed solution is deposited by spin-casting on a substrate, namely, quartz or ITO-coated glass for characterization, or ITO-coated glass with DB film for OLEDs. The resulting films are annealed at 135° C. for 1 hour. For ITO-coated glass sample, Al is then thermally deposited to finish the full stack of the OLED. For some devices, a layer of electron-transporting materials, namely, polypyridine, may be deposited by spin-casting on top of the functionalized polymer-nanocrystal complex E-semi-IPN film.

### Example 11

### Preparation of X1-Solution

To a vial are added polyethylene glycoldi(meth)acrylate (20%), ethoxylated bisphenol A dimethylacrylate (40%), dimethylacrylate (35%) and di-n-propyl peroxydicarbonate (5%). Carbon tetrachloride, as solvent, is added to the above mixture to form a solution (referred to herein as X1-solution) with a concentration of 10%.

### Example 12

### Preparation of Another Embodiment of a Polymer-Only E-semi-IPN

To X1-solution (1 mL), prepared as described above in Example 11, is added a solution of PFO (6 mg) in toluene (1 mL). The resulting mixture is stirred for 1 hour at room temperature. The well-mixed solution is deposited by spin-casting on a quartz substrate (for characterization) and on an ITO-coated glass with DuPont™ Buffer™ (DB) film (for OLEDs). The resulting films (PFO-based) are annealed at 135° C. for 1 hour and cooled to room temperature for future use.

Although the foregoing invention has been described in some detail by way of illustration and example for purposes of clarity of understanding, it will be readily apparent to those of ordinary skill in the art in light of the teachings of this invention that certain changes and modifications may be made thereto without departing from the spirit or scope of the appended claims. Furthermore, the foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description; they are not intended to be exhaustive or to limit the invention to the precise forms disclosed. Many modifications and variations are possible in view of the above teachings. The embodiments were chosen and described in order to explain the principles of the invention and its practical applications and to thereby enable others skilled in the art to utilize the invention.

What is claimed is:

1. An emissive semi-interpenetrating polymer network comprising:
(a) a semi-interpenetrating polymer network comprising in a crosslinked state:
(i) one or more of a polymerized organic monomer and a polymerized organic oligomer,
(ii) polymerized water soluble polymerizable agent, and
(iii) one or more polymerized polyfunctional cross-linking agents; and
(b) an emissive material interlaced in the polymer network.

2. The emissive semi-interpenetrating polymer network of claim 1, wherein the one or more of a polymerized organic monomer and a polymerized organic oligomer is one or more of a polymerized diacrylate, a polymerized triacrylate and a polymerized tetraacrylate.

3. The emissive semi-interpenetrating polymer network of claim 1, wherein the polymerized polyfunctional cross-linking agent is one or more of a polymerized diacrylate, a polymerized ,triacrylate and a polymerized tetraacrylate.

4. The emissive semi-interpenetrating polymer network of claim 1, wherein the polymerized polyfunctional cross-linking agent comprises a portion that is one or both of the polymerized organic monomer and the polymerized organic oligomer.

5. The emissive semi-interpenetrating polymer network of claim 1, wherein the water soluble polymerizable agent is a hydrophilic monomer or a hydrophilic oligomer.

6. The emissive semi-interpenetrating polymer network of claim 1, wherein the water soluble polymerizable agent is an acrylamide, a vinyl amide, a cationic monomer, or an anionic monomer, or a derivative thereof

7. The emissive semi-interpenetrating polymer network of claim 1, wherein the emissive material is one of an emissive organic polymer, a nanocrystal and a combination of an emissive organic polymer and a nanocrystal.

8. An organic light emitting device comprising:
(a) a first electrode;
(b) a second electrode; and
(c) an emissive semi-interpenetrating polymer network disposed between the first electrode and the second electrode, the emissive semi-interpenetrating polymer network comprising:
(i) a semi-interpenetrating polymer network comprising in a crosslinked state:
(I) one or more of a polymerized organic monomer and a polymerized organic oligomer,
(II) polymerized water soluble polymerizable agent, and
(III) one or more polymerized polyfunctional cross-linking agents; and
(ii) an emissive material interlaced in the polymer network.

9. The organic light emitting device of claim 8, wherein the emissive semi-interpenetrating polymer network is disposed on a substrate.

10. The organic light emitting device of claim 8, wherein the one or more of a polymerized organic monomer and a polymerized organic oligomer is one or more of a polymerized diacrylate, a polymerized triacrylate and a polymerized tetraacrylate.

11. The organic light emitting device of claim 8, wherein the polymerized polyfunctional cross-linking agent is one or more of a polymerized diacrylate, a polymerized triacrylate and a polymerized tetraacrylate.

12. The organic light emitting device of claim 8, wherein the water soluble polymerizable agent is a hydrophilic monomer or a hydrophilic oligomer.

13. The organic light emitting device of claim 8, wherein the emissive material is one of an emissive organic polymer, a nanocrystal and a combination of an emissive organic polymer and a nanocrystal.

14. The organic light emitting device of claim 8, further comprising one or more of a hole injecting layer, a hole transporting layer, an electron transporting layer and an electron injecting layer disposed between the first electrode and the second electrode.

15. An emissive semi-interpenetrating polymer network comprising:
(a) a semi-interpenetrating polymer network comprising in a crosslinked state:
(i) at least two of a polymerized diacrylate, a polymerized triacrylate and a polymerized tetraacrylate, and
(ii) at least one of a polymerized acrylamide and a polymerized vinyl amide, and
(b) a polyfluorene, a polyfluorene derivative, a nanocrystal-polyfluorene hybrid, or a nanocrystal-polyfluorene derivative hybrid interlaced in the polymer network.
